(19) United States
(12) Patent Application Publication
(10) Pub. No.: US 2026/0076129 A1
(43) Pub. Date: Mar. 12, 2026

(54) SUBSTRATE PROCESSING APPARATUS, SUBSTRATE PROCESSING METHOD AND SUBSTRATE PROCESSING SYSTEM

(71) Applicant: SCREEN HOLDINGS CO., LTD., Kyoto (JP)

(72) Inventor: Shuhei NEMOTO, Kyoto (JP)

(21) Appl. No.: 19/107,451

(22) PCT Filed: Jul. 24, 2023
(86) PCT No.: PCT/JP2023/026932

§ 371 Date: Feb. 27, 2025

(30) Foreign Application Priority Data
Aug. 29, 2022 (JP) 2022-135573

(51) Int. Cl. H01L 21/67

(52) U.S. Cl. CPC H10P 72/0404

(57) ABSTRACT

A substrate processing apparatus has an outside flow straightening member and an inside flow straightening member. The outside flow straightening member straightens a gas passing between an upper sealing member and a lower sealing member so as to form an air curtain.

When formation of an atmosphere separated space is released, the inside flow straightening member moves up and down integrally with the lower sealing member while the outside flow straightening member is attached to the upper sealing member and is maintained at a fixed position. This generates a differential pressure between an exit side of the outside flow straightening member and an exit side of the inside flow straightening member to increase the flow rate of the gas to flow downward from the outside flow straightening member along the outer side surface of the lower sealing member. Thus, the air curtains are reinforced.

### TECHNICAL FIELD

This invention relates to substrate processing techniques for processing a substrate by supplying a processing liquid to the substrate.

The disclosure of Japanese Patent Application No. 2022-135573 filed on Aug. 29, 2022 including specification, drawings and claims is incorporated herein by reference in its entirety.

### BACKGROUND

There is a known substrate processing apparatus which performs substrate processing such as chemical liquid processing or cleaning processing by supplying a processing liquid to a substrate such as a semiconductor wafer while rotating the substrate. According to an apparatus described in Patent Document 1, for example, a processing liquid is supplied to a substrate while the substrate is held by a spin chuck and is rotating in a processing chamber. In this apparatus, three cup members are prepared in order to capture and collect the processing liquid scattered from the substrate supplied with the processing liquid. One of these cup members moves up and an upper end part thereof comes into contact with a ceiling of the processing chamber. By doing so, a sealed space (corresponding to one example of an “atmosphere separated space” of the present invention) is formed in the processing chamber. After a head goes into the sealed space, the processing liquid is supplied from the head to the substrate.

### CITATION LIST

### Patent Literature

[Patent Literature 1] Japanese Patent No. 6282904

### SUMMARY

### Technical Problem

While the sealed space is formed, atmosphere separation is formed between a space surrounded by the cup member and an outside space of the cup member. During loading and unloading of the substrate into and from the spin chuck, centering processing and observation processing described later, maintenance processing on the substrate processing apparatus, and others, however, the cup member for forming the sealed space moves down to release formation of the atmosphere separation. In doing this, a foreign matter such as particles existing in the outside space of the cup member might flow in toward the spin chuck. This arises a desire for a technique for suppressing such incoming flow of a foreign matter.

This invention is intended to solve the above-described problem. In a substrate processing apparatus to perform substrate processing in an atmosphere-separated processing space, it is an object of the present invention to suppress flow of a foreign matter into the processing space even when formation of the atmosphere separation is released.

### Solution to Problem

A first aspect of the invention is a substrate processing apparatus. The apparatus comprises: a chamber having an internal space; a substrate holder provided rotatably about an axis of rotation extending in a vertical direction while holding a substrate to be substantially horizontal in the internal space; a rotating mechanism configured to rotate the substrate holder about the axis of rotation; a processing mechanism configured to perform substrate processing on the substrate by supplying a processing liquid to the substrate held by the substrate holder rotated by the rotating mechanism; a scattering preventing mechanism configured to collect and discharge the processing liquid scattered from the substrate by the rotation of the substrate holder while surrounding an outer periphery of the substrate; a gas supplier configured to supply gas from a first opening provided in a ceiling wall of the chamber into the internal space; an atmosphere separating mechanism having a tube-shape upper sealing member and a tube-shape lower sealing member and being configured to allow formation of an atmosphere separated space separated from a surrounding environment by causing the lower sealing member and the upper sealing member to surround a space extending toward a central part of the first opening from a processing space surrounded by the scattering preventing mechanism, the tube-shape upper sealing member attached from a side of the internal space to the ceiling wall in such a manner as to surround the first opening entirely, the tube-shape lower sealing member provided movably in the vertical direction with an outer peripheral surface of the lower sealing member overlapping an inner peripheral surface of the upper sealing member in the vertical direction; an outside flow straightening member attached to the upper sealing member in such a manner as to straighten the flow of the gas passing between the upper sealing member and the lower sealing member to cause the gas to flow downward along an outer side surface of the lower sealing member; an inside flow straightening member provided movably up and down integrally with the lower sealing member in such a manner as to straighten the flow of the gas passing inside the lower sealing member to cause the gas to flow in the processing space; an elevating mechanism configured to move the lower sealing member up and down; and a control unit configured to control the elevating mechanism in such a manner as to form the atmosphere separated space by moving the lower sealing member down to a predetermined lower limit position in the vertical direction, and to allow access to the processing space and to increase the flow rate of the gas flowing downward along the outer side surface of the lower sealing member by moving the lower sealing member up to a retracted position vertically above the lower limit position.

A second aspect of the invention is a substrate processing method of performing substrate processing on a substrate by supplying a processing liquid to the substrate while causing a scattering preventing mechanism to surround an outer periphery of the substrate rotating in an internal space of a chamber to which gas is supplied via a first opening provided in a ceiling wall of the chamber. The method comprises: a first step of forming an atmosphere separated space which surrounds a space extending toward a central part of the first opening from a processing space surrounded by the scattering preventing mechanism and is separated from a surrounding environment by moving a tube-shape lower sealing member down to a predetermined lower limit position in a vertical direction while making an overlap of an outer peripheral surface of the lower sealing member in the vertical direction with an inner peripheral surface of a tube-shape upper sealing member attached from a side of the internal space to the ceiling wall in such a manner as to surround the first opening entirely; and a second step of releasing formation of the atmosphere separated space and forming a gap between the lower sealing member and the scattering preventing mechanism in the vertical direction by moving the lower sealing member up to a retracted position vertically above the lower limit position, wherein the first step includes a step of straightening the flow of the gas passing between the upper sealing member and the lower sealing member using an outside flow straightening member attached to the upper sealing member and causing the gas to flow downward along an outer side surface of the lower sealing member, and straightening the flow of the gas passing inside the lower sealing member using an inside flow straightening member provided movably integrally with the lower sealing member and causing the gas to flow in the processing space, and a second step includes a step of making the flow rate of the gas flowing downward along the outer side surface of the lower sealing member higher than a flow rate in the first step as the inside flow straightening member moves up integrally with the lower sealing member.

A third aspect of the invention is a substrate processing system. The system comprises: a plurality of the above substrate processing apparatuses; and an exhaust device connected in parallel to the plurality of substrate processing apparatuses and configured to exhaust a plurality of the internal spaces simultaneously, wherein each of the plurality of substrate processing apparatuses includes: a first exhaust pipe forming connection between the processing space and the exhaust device; a second exhaust pipe forming connection between a space in the internal space and other than the processing space and the exhaust device; and an exhaust flow rate adjuster configured to make a ratio adjustable between a first exhaust flow rate of exhaust via the first exhaust pipe and a second exhaust flow rate of exhaust via the second exhaust pipe, wherein the control unit is configured to control the exhaust flow rate adjuster in such a manner that an exhaust flow rate of exhaust per unit time by the exhaust device from the internal space becomes constant by making the ratio of the first exhaust flow rate higher when the lower sealing member is positioned at the lower limit position and making the ratio of the second exhaust flow rate higher when the lower sealing member is positioned at the retracted position.

According to the invention having the foregoing configuration, when the lower sealing member moves down to the predetermined lower limit position while the outer peripheral surface of the lower sealing member makes an overlap in the vertical direction with the inner peripheral surface of the upper sealing member attached to the ceiling wall, the atmosphere separated space is formed which is separated from a surrounding environment while surrounding the space extending toward the central part of the first opening from the processing space. On the other hand, when the lower sealing member moves up to the retracted position vertically above the lower limit position, formation of the atmosphere separated space is released and the gap is formed between the lower sealing member and the scattering preventing mechanism in the vertical direction. At this time, a concern for flow of a foreign matter into the processing space arises. In this regard, according to the present invention, the outside flow straightening member straights the flow of the gas passing between the upper sealing member and the lower sealing member to cause the gas to flow downward along the outer side surface of the lower sealing member. By doing so, a so-called air curtain is formed in such a manner as to surround the processing space. Furthermore, when formation of the atmosphere separated space is released, the inside flow straightening member for straightening the flow of the gas passing inside the lower sealing member and causing the gas to flow in the processing space moves up and down integrally with the lower sealing member while the outside flow straightening member is attached to the upper sealing member and is maintained at a fixed position. This generates a differential pressure between an exit side of the outside flow straightening member and an exit side of the inside flow straightening member to increase the flow rate of the gas to flow downward from the outside flow straightening member along the outer side surface of the lower sealing member. Specifically, the flow rate of the gas forming the air curtain increases to enhance barrier performance of blocking incoming flow of a foreign matter. As a result, it is possible to suppress flow of a foreign matter into the processing space more effectively using the air curtain.

### Advantageous Effects of Invention

According to this invention, it is possible to prevent flow of a foreign matter into a processing space during substrate processing in an atmosphere-separated processing space and also possible to effectively suppress flow of a foreign matter into the processing space even in a state where formation of the atmosphere separation is released.

All of a plurality of constituent elements of each aspect of the invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the invention described above can be combined with some or all of technical features included in another aspect of the invention described above to obtain one independent form of the invention in order to solve some or all of the aforementioned problems or to achieve some or all of the effects described in this specification.

### BRIEF DESCRIPTION OF DRAWINGS

FIG. 1 is a plan view showing a schematic configuration of a substrate processing system equipped with a first embodiment of a substrate processing apparatus according to the invention.

FIG. 2 is a diagram schematically showing the configuration of the processing block.

FIG. 3 is a diagram showing a configuration of the first embodiment of the substrate processing apparatus according to the invention.

FIG. 4 is a diagram schematically showing a configuration of a chamber and a configuration attached to the chamber.

FIG. 5 is a plan view schematically showing the configuration of the substrate processing part installed on the base member.

FIG. 6 is a perspective view showing a configuration of the holding/rotating mechanism.

FIG. 7 is a diagram showing a dimensional relationship of the substrate held on the spin chuck and the rotating cup.

FIG. 8A is a diagram schematically showing a status in each part of the apparatus during the bevel processing.

FIG. 8B is a diagram schematically showing a status in each part of the apparatus during shutter opening processing.

FIG. 8C is a diagram schematically showing a status in each part of the apparatus during substrate conveyance.

FIG. 8D is a diagram schematically showing a status in each part of the apparatus during centering processing and observation processing.

FIG. 9 is a diagram schematically showing the configuration and operation of the centering mechanism.

FIG. 10 is a perspective view showing an observation head of the substrate observing mechanism.

FIG. 11 is an exploded assembly perspective view of the observation head shown in FIG. 10.

FIG. 12 is a flowchart showing the bevel processing performed, as an example of a substrate processing operation, by the substrate processing apparatus shown in FIG. 3.

FIG. 13 is a diagram showing a state in each part of the apparatus corresponding to each status of the substrate processing operation.

FIG. 14 is a diagram showing a state in each part of the apparatus corresponding to each status of the maintenance processing.

FIG. 15A is a diagram schematically showing a status in each part of the apparatus during first maintenance processing.

FIG. 15B is a diagram schematically showing a status in each part of the apparatus during second maintenance processing.

FIG. 15C is a diagram schematically showing a status in each part of the apparatus during third maintenance processing.

### DESCRIPTION OF EMBODIMENTS

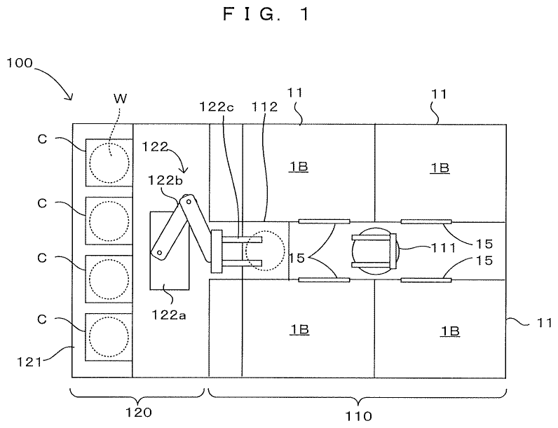

FIG. 1 is a plan view showing a schematic configuration of a substrate processing system equipped with a first embodiment of a substrate processing apparatus according to the invention. This figure is a diagram not showing the external appearance of the apparatus, but showing an internal structure of a substrate processing system 100 by excluding an outer wall panel and other partial configurations. This substrate processing system 100 is, for example, a single-wafer type apparatus installed in a clean room and configured to process substrates W each having a circuit pattern (hereinafter, referred to as a “pattern”) only on one principal surface one by one. Then, substrate processing using a processing liquid is performed in a processing unit 1 equipped in the substrate processing system 100. In this specification, a pattern formation surface (one principal surface) formed with the pattern is referred to as a “front surface” and the other principal surface not formed with the pattern on an opposite side is referred to as a “back surface”. Further, a surface facing down is referred to as a “lower surface” and a surface facing up is referred to as an “upper surface”. Further, in this specification, the “pattern formation surface” means a surface of the substrate where an uneven pattern is formed in an arbitrary region regardless of whether the surface is flat, curved or uneven.

Here, various substrates such as semiconductor wafers, glass substrates for photomask, glass substrates for liquid crystal display, glass substrates for plasma display, substrates for FPD (Flat Panel Display), optical disk substrates, magnetic disk substrates and magneto-optical disk substrates can be applied as the “substrate” in the present embodiment. Although the substrate processing apparatus used in processing semiconductor wafers is mainly described as an example with reference to the drawings below, application to the processing of various substrates illustrated above is also possible.

As shown in FIG. 1, the substrate processing system 100 includes a substrate processing station 110 for processing the substrate W and an indexer station 120 coupled to this substrate processing station 110. The indexer station 120 includes a container holder 121 capable of holding a plurality of containers C for housing the substrates W (FOUPs (Front Opening Unified Pods), SMIF (Standard Mechanical Interface) pods, OCs (Open Cassettes) for housing a plurality of the substrates W in a sealed state), and an indexer robot 122 for taking out an unprocessed substrate W from the container C by accessing the container C held by the container holder 121 and housing a processed substrate W in the container C. A plurality of the substrates W are housed substantially in a horizontal posture in each container C.

The indexer robot 122 includes a base 122a fixed to an apparatus housing, an articulated arm 122b provided rotatably about a vertical axis with respect to the base 122a, and a hand 122c mounted on the tip of the articulated arm 122b. The hand 122c is structured such that the substrate W can be placed and held on the upper surface thereof. Such an indexer robot including the articulated arm and the hand for holding the substrate is not described in detail since being known.

The substrate processing station 110 includes a mounting table 112 on which the indexer robot 122 places the substrate W, a substrate conveyor robot 111 arranged substantially in a center in a plan view and a plurality of processing blocks 1B are arranged to surround this substrate conveyor robot 11. Specifically, the four processing blocks 1B are arranged to face the space where the substrate conveyor robot 111 is arranged.

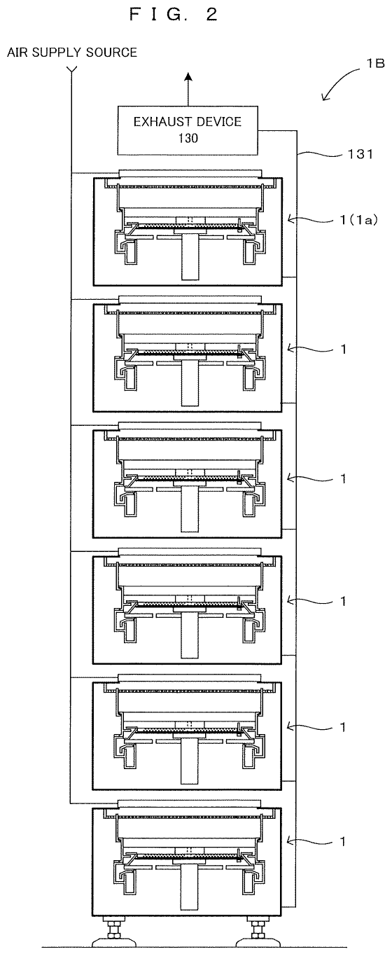

FIG. 2 is a diagram schematically showing the configuration of the processing block. Each processing block 1B includes a plurality of (in the present embodiment, six) processing units 1 and one exhaust device 130. The six processing units 1 are stacked in a vertical direction Z, and the exhaust device 130 is arranged above the processing unit 1 (a unit denoted by a sign la in this figure) at the highest position. All the processing units 1 are connected in parallel to the exhaust device 130 via a common pipe 131. Thus, up to six processing units 1 are exhausted simultaneously with each other. By stacking the plurality of processing units 1 and the exhaust device 130 in this way, it becomes possible to reduce a footprint occupied by the processing units 1 in the substrate processing system 100.

The substrate conveyor robot 111 randomly accesses the mounting table 112 for the processing units 1 configured in this way and transfers the substrate W to and from the mounting table 112. On the other hand, each processing unit 1 performs a predetermined processing to the substrate W, and corresponds to the substrate processing apparatus according to the present invention. In the present embodiment, these processing units (substrate processing apparatus) 1 have the same function. Thus, a plurality of the substrates W can be processed in parallel. If the substrate conveyor robot 111 can directly transfer the substrate W from the indexer robot 122, the mounting table 112 is not necessarily required.

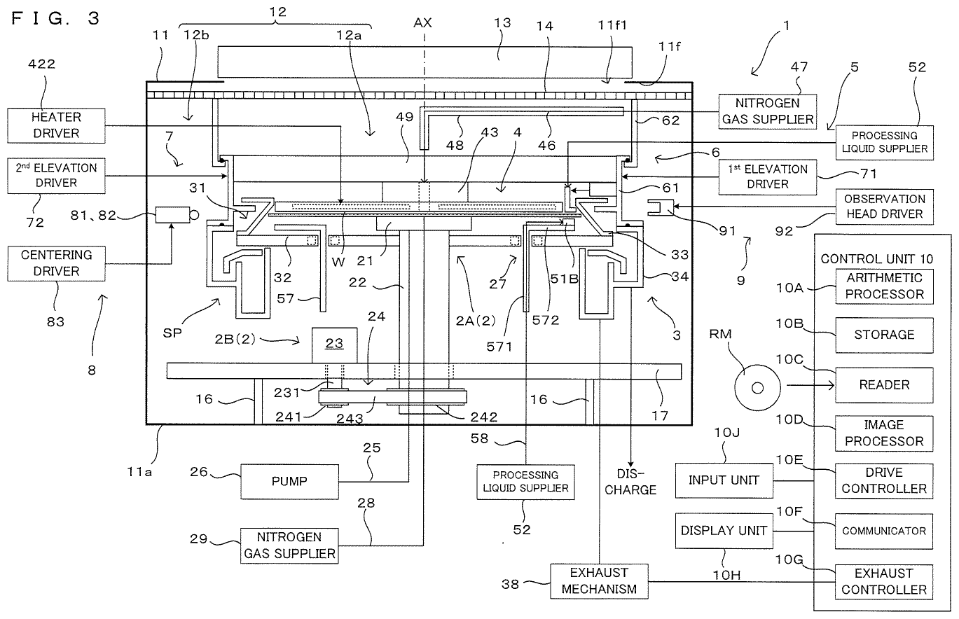

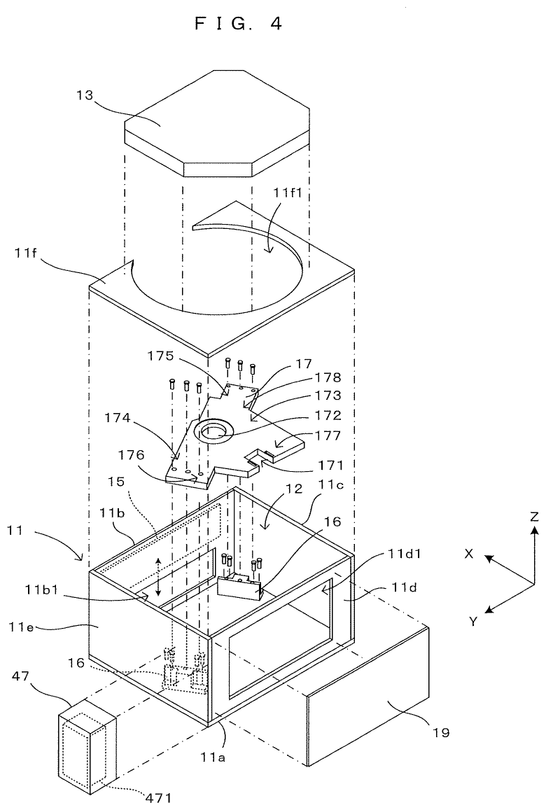

FIG. 3 is a diagram showing a configuration of the first embodiment of the substrate processing apparatus according to the invention. Further, FIG. 4 is a diagram schematically showing a configuration of a chamber and a configuration attached to the chamber. In FIGS. 3 and 4 and each figure to be referred to below, the dimensions and numbers of respective components may be shown in an exaggerated or simplified manner to facilitate understanding. As shown in FIG. 4, a chamber 11 used in the substrate processing apparatus (processing unit) 1 has a bottom wall 11a having a rectangular shape in a plan view vertically from above, four sidewalls 11b to 11e standing from a periphery of the bottom wall 11a, and a ceiling wall 11f covering respective upper end parts of the sidewalls 11b to 11e. By combining the bottom wall 11a, the sidewalls 11b to 11e, and the ceiling wall 11f, formed is an internal space 12 having a substantially rectangular parallelopiped shape.

On an upper surface of the bottom wall 11a, base support members 16 and 16 are fixed away from each other by fastener components such as bolts or the like. Specifically, the base support member 16 stands from the bottom wall 11a. On respective upper end parts of these base support members 16 and 16, a base member 17 is fixed by the fastener components such as bolts or the like. This base member 17 has a plane size smaller than that of the bottom wall 11a and is composed of a plate having a thickness larger than that of the bottom wall 11a and rigidity higher than that thereof. As shown in FIG. 3, the base member 17 is raised by the base support members 16 and 16 from the bottom wall 11a vertically upward. In other words, a so-called raised floor structure is formed on a bottom part of the internal space 12 of the chamber 11. As described later, an upper surface of this base member 17 is finished to allow a substrate processing part SP for performing substrate processing on the substrate W to be installed thereon, and the substrate processing part SP is installed on the upper surface thereof. Components constituting this substrate processing part SP are electrically connected to a control unit 10 for controlling the entire apparatus and operate in response to commands from the control unit 10. Further, the shape of the base member 17 and the configuration and operation of the substrate processing part SP will be described in detail.

As shown in FIGS. 3 and 4, a fan filter unit (FFU) 13 is attached to a ceiling wall 11f of the chamber 11. This fan filter unit 13 further cleans air in a clean room in which the substrate processing apparatus 1 is installed, and supplies the cleaned air into an internal space 12 of the chamber 11. The fan filter unit 13 includes a fan and a filter (e.g. a HEPA (High Efficiency Particulate Air) filter) for taking in the air in the clean room and feeding the air into the chamber 11, and feeds the cleaned air via an opening 11f1 provided in the ceiling wall 11f. In this way, a downflow of the cleaned air is formed in the internal space 12 in the chamber 11. In order for the cleaned air supplied from the fan filter unit 13 to be dispersed uniformly, two types of punching plates perforated with a multitude of air outlets and functioning as an inside flow straightening member 14a and an outside flow straightening member 14b are provided right below the ceiling wall 11f. The inside flow straightening member 14a is attached to a lower sealing cup member 61 described later and moves in the vertical direction Z integrally with the lower sealing cup member 61. The outside flow straightening member 14b is attached to an upper sealing cup member 62 described later and is fixedly arranged at a constant height position in the vertical direction Z. The specific configurations and functions of the inside flow straightening member 14a and the outside flow straightening member 14b will be describe later in detail.

As shown in FIG. 4, in the substrate processing apparatus 1, a conveyance opening 11b1 is provided in the sidewall 11b facing the substrate conveyor robot 111 among the four sidewalls 11b to 11e, and the internal space 12 communicates with the outside of the chamber 11 therethrough. For this reason, a hand (not shown) of the substrate conveyor robot 111 can access the substrate processing part SP through the conveyance opening 11b1. In other words, by providing the conveyance opening 11b1, the substrate W can be loaded into or unloaded from the internal space 12. Further, a shutter 15 for opening and closing this conveyance opening 11b1 is attached to the sidewall 11b.

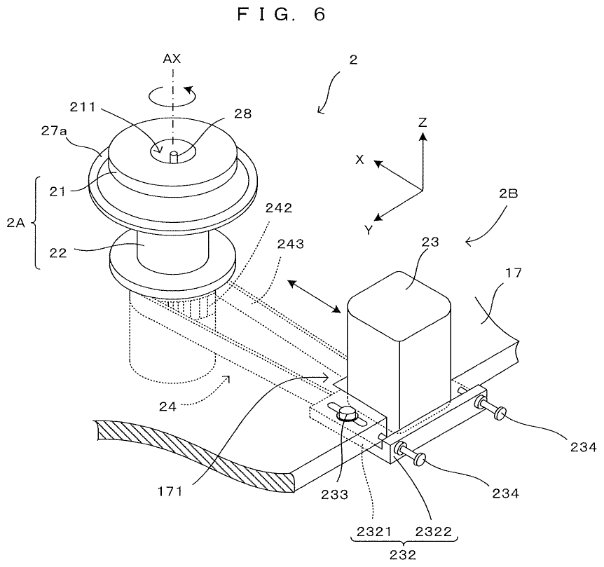

A shutter opening/closing mechanism (not shown) is connected to the shutter 15, and opens or closes the shutter 15 in response to an opening/closing command from the control unit 10. More specifically, in the substrate processing apparatus 1, the shutter opening/closing mechanism opens the shutter 15 in carrying an unprocessed substrate W into the chamber 11, and the unprocessed substrate W is carried in a face-up posture to the substrate processing part SP of the rotating mechanism 2 by a hand of a substrate conveyor robot 111. That is, the substrate W is placed on the spin chuck (denoted by 21 in FIG. 6) with an upper surface Wf facing up. If the hand of the substrate conveyor robot 111 is retracted from the chamber 11 after the substrate W is carried into, the shutter opening/closing mechanism closes the shutter 15. Then, a bevel processing is performed on the peripheral edge part Ws of the substrate W, as an example of a “substrate processing” of the invention by the substrate processing part SP, in the processing space (equivalent to a sealed space SPs to be described in detail later) of the chamber 11. Further, after the bevel processing is finished, the shutter opening/closing mechanism opens the shutter 15 again and the hand of the substrate conveyor robot 111 carries out the processed substrate W from the substrate processing part SP. As just described, in the present embodiment, the internal space 12 of the chamber 11 is kept in a normal temperature atmosphere. Note that the “normal temperature” means a temperature in a range of 5° C. to 35° C. in this specification.

As shown in FIG. 4, the sidewall 11d is positioned on the opposite side of the sidewall 11b with respect to the substrate processing part SP (FIG. 3) installed on the base member 17. In this sidewall 11d, provided is a maintenance opening 11d1. During maintenance, as shown in this figure, the maintenance opening 11d1 is opened. For this reason, an operator can access the substrate processing part SP through the maintenance opening 11d1 from the outside of the apparatus. On the other hand, during the substrate processing, a lid member 19 is so attached as to close the maintenance opening 11d1. Thus, in the present embodiment, the lid member 19 is detachable from the sidewall 11d.

Further, on an outer surface of the sidewall 11e, a heated gas supplier 47 for supplying the substrate processing part SP with a heated inert gas (nitrogen gas in the present embodiment) is attached. This heated gas supplier 47 incorporates a heater 471.

Thus, on the outer wall side of the chamber 11, the shutter 15, the lid member 19, and the heated gas supplier 47 are arranged. In contrast to this, in an inner side of the chamber 11, i.e., in the internal space 12, the substrate processing part SP is installed on the upper surface of the base member 17 having the raised floor structure. Hereinafter, with reference to FIGS. 3, 5-7, 8A-8C, 9-10 and 11, the configuration of the substrate processing part SP will be described.

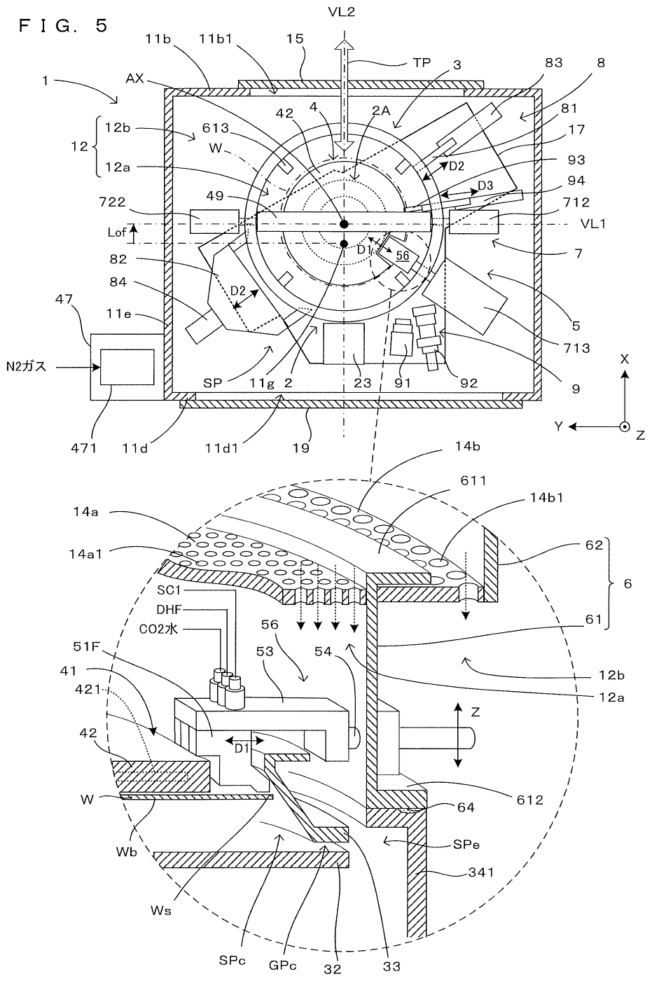

FIG. 5 is a plan view schematically showing the configuration of the substrate processing part installed on the base member. Hereinafter, for clarifying the arrangement relation and operation of the components of the apparatus, a coordinate system with a Z direction as a vertical direction and with an XY plane as a horizontal plane is shown as appropriate. In the coordinate system of FIG. 5, it is assumed that a horizontal direction in parallel to a conveyance path TP of the substrate W is an “X direction” and a horizontal direction orthogonal to the X direction is a “Y direction”. In more detail, directions from the internal space 12 of the chamber 11 toward the conveyance opening 11b1 and the maintenance opening 11d1 are referred to as a “+X direction” and a “−X direction”, respectively, direction s from the internal space 12 of the chamber 11 toward the sidewalls 11c and 11e are referred to as a “−Y direction” and a “+Y direction”, respectively, and directions vertically upward and downward are referred to as a “+Z direction” and a “−Z direction”, respectively.

The substrate processing part SP includes a holding/rotating mechanism 2, a scattering preventing mechanism 3, an upper surface protecting/heating mechanism 4, a processing mechanism 5, an atmosphere separating mechanism 6, an elevating mechanism 7, a centering mechanism 8, and a substrate observing mechanism 9. These mechanisms are provided on the base member 17. Specifically, with reference to the base member 17 having rigidity higher than that of the chamber 11, the holding/rotating mechanism 2, the scattering preventing mechanism 3, the upper surface protecting/heating mechanism 4, the processing mechanism 5, the atmosphere separating mechanism 6, the elevating mechanism 7, the centering mechanism 8, and the substrate observing mechanism 9 are arranged to one another with a positional relation determined in advance.

FIG. 6 is a perspective view showing a configuration of the holding/rotating mechanism. The holding/rotating mechanism 2 includes a substrate holder 2A for holding the substrate W substantially in a horizontal posture with a surface of the substrate W facing up and a rotating mechanism 2B for synchronously rotating the substrate holder 2A holding the substrate W and part of the scattering preventing mechanism 3. For this reason, when the rotating mechanism 2B operates in response to a rotation command from the control unit 10, the substrate W and a rotating cup 31 of the scattering preventing mechanism 3 are rotated about an axis of rotation AX extending in parallel to the vertical direction Z.

The substrate holder 2A includes the spin chuck 21 which is a disk-like member smaller than the substrate W. The spin chuck 21 is so provided that an upper surface thereof is substantially horizontal and a center axis thereof coincides with the axis of rotation AX. Especially in the present embodiment, as shown in FIG. 5, a center of the substrate holder 2A (which corresponds to the center axis of the spin chuck 21) is offset in the (+X) direction relative to a center 11g of the chamber 11. Specifically, the substrate holder 2A is arranged so that the center axis (axis of rotation AX) of the spin chuck 21 may be positioned at a processing position deviated from the center 11g of the internal space 12 toward a side of the conveyance opening 11b1 by a distance L of in a plan view of the chamber 11 viewed from above. Further, for clarifying the later-described arrangement relation of the components of the apparatus, in the present specification, a virtual line passing through the center (axis of rotation AX) of the substrate holder 2A which is offset and being orthogonal to the conveyance path TP and another virtual line in parallel to the conveyance path TP are referred to as a “first virtual horizontal line VL1” and a “second virtual horizontal line VL2”, respectively.

As shown in FIG. 6, a cylindrical rotary shaft 22 is coupled to a lower surface of the spin chuck 21. The rotary shaft 22 extends in the vertical direction Z with an axis line thereof coinciding with the axis of rotation AX. Further, the rotating mechanism 2B is connected to the rotary shaft 22.

The rotating mechanism 2B has a motor 23 which generates a rotational driving force for rotating the substrate holder 2A and the rotating cup 31 of the scattering preventing mechanism 3 and a power transmitter 24 for transmitting the rotational driving force. The motor 23 has a rotation shaft 231 rotating with generation of the rotational driving force. The motor 23 is provided at a motor attachment portion 171 of the base member 17 in a posture with the rotation shaft 231 extending vertically downward. In more detail, as shown in FIG. 4, the motor attachment portion 171 is a portion which is cut out in the (+X) direction while facing the maintenance opening 11d1. A cutout width (size in the Y direction) of this motor attachment portion 171 is almost equal to the width of the motor 23 in the Y direction. For this reason, the motor 23 is movable in the X direction with a side surface thereof engaged with the motor attachment portion 171.

In order to fix the motor 23 to the base member 17 at the motor attachment portion 171 while positioning the motor 23 in the X direction, a motor fixing bracket 232 is coupled to the base member 17 with a fastening member 233 such as a bolt, a screw, or the like. As shown in FIG. 6, the motor fixing bracket 232 has a horizontal portion 2321 and a vertical portion 2322 and has a substantial L shape in a side view from the (+Y) direction. Though not shown in FIG. 6, at a central part of the horizontal portion 2321 of the motor fixing bracket 232, provided is a through hole through which the rotation shaft 231 is to be inserted. The horizontal portion 2321 supports the motor 23 with the rotation shaft 231 inserted vertically downward through this through hole. Further, the vertical portion 2322 is so structured as to be engaged with the motor 23 supported by the horizontal portion 2321 from below. To this vertical portion 2322, two fastening members 234 such as bolts, screws, or the like are attached, being away from each other in the Y direction. A tip part of each of the fastening members 234 penetrates the vertical portion 2322, extending in the (+X) direction, and is threadedly engaged in the motor attachment portion 171. Therefore, the operator positively or negatively rotates the fastening member 234, to thereby move the motor fixing bracket 232 supporting the motor 23 in the X direction. It thereby becomes possible to position the motor 23 in the X direction. Further, after positioning the motor 23, the operator positively rotates the fastening member 233, to thereby firmly fix the motor 23 to the base member 17 integrally with the motor attachment portion 171.

At a tip part of the rotation shaft 231 protruding downward from the base member 17, attached is a first pulley 241. At a lower end part of the substrate holder 2A, attached is a second pulley 242. In more detail, the lower end part of the substrate holder 2A is inserted into the through hole provided in a spin chuck attachment portion 172 of the base member 17 and protrudes downward from the base member 17. This protruding portion is provided with the second pulley 242. Then, an endless belt 243 is put over between the first pulley 241 and the second pulley 242. Thus, in the present embodiment, the first pulley 241, the second pulley 242, and the endless belt 243 constitute the power transmitter 24.

In a case of using the power transmitter 24 having such a configuration, a long-length timing belt can be selected as the endless belt 243 and a longer life of the endless belt 243 is ensured. With the movement of the motor 23 in the X direction, however, a maintenance work such as spacing adjustment of the first pulley 241 and the second pulley 242, exchange of the endless belt 243, or the like is needed. Then, in the present embodiment, as shown in FIG. 5, the conveyance opening 11b1, the substrate holder 2A, the power transmitter 24, the motor 23, and the maintenance opening 11d1 are linearly arranged in this order along the second virtual horizontal line VL2 in a plan view of the chamber 11 viewed from above. In other words, the power transmitter 24 and the motor 23 are so arranged as to face the maintenance opening 11d1. Therefore, when the maintenance opening 11d1 is opened by detaching the lid member 19 from the chamber 11, the power transmitter 24 and the motor 23 are exposed to the outside through the maintenance opening 11d1. As a result, it becomes easier for the operator to perform the maintenance process and it is possible to increase the efficiency of the maintenance work.

Moreover, the power transmitter 24 is disposed below the base member 17 while the other mechanisms described below are disposed above the base member 17. By adopting such an arrangement, it is possible for the operator to perform the maintenance work more efficiently without interference with any of the other mechanisms.

As shown in FIG. 6, a through hole 211 is provided at a central part of the spin chuck 21 and communicates with an internal space of the rotary shaft 22. A pump 26 is connected to the internal space via a pipe 25 having a valve (not shown) disposed therein. This pump 26 and the valve are electrically connected to the control unit 10 and operate in response to a command from the control unit 10. In this way, a negative pressure and a positive pressure are selectively applied to the spin chuck 21. If the pump 26 applies a negative pressure to the spin chuck 21, for example, with the substrate W placed substantially in a horizontal posture on the upper surface of the spin chuck 21, the spin chuck 21 sucks and holds the substrate W from below. On the other hand, if the pump 26 applies a positive pressure to the spin chuck 21, the substrate W can be taken out from the upper surface of the spin chuck 21. Further, if the suction of the pump 26 is stopped, the substrate W is horizontally movable on the upper surface of the spin chuck 21.

A nitrogen gas supplier 29 is connected to the spin chuck 21 via a pipe 28 provided in a central part of the rotary shaft 22. The nitrogen gas supplier 29 supplies a nitrogen gas at a normal temperature supplied from a utility of a factory, in which the substrate processing system 100 is installed, to the spin chuck 21 at a flow rate and a timing corresponding to a nitrogen gas supply command from the control unit 10, and causes the nitrogen gas to flow from the central part to a radially outer side on the side of a lower surface Wb of the substrate W. Note that although the nitrogen gas is used in the present embodiment, another inert gas may be used. This point also applies to a heated gas discharged from a central nozzle to be described later. Further, the “flow rate” means a moving amount of a fluid such as the nitrogen gas per unit time.

The rotating mechanism 2B includes a power transmitter 27 (FIG. 3) for not only rotating the spin chuck 21 integrally with the substrate W, but also rotating the rotating cup 31 in synchronization with the former rotation. The power transmitter 27 includes an annular member 27a (FIG. 6) made of a non-magnetic material or resin, spin chuck side magnets (not shown) built-in the annular member 27a, and cup side magnets (not shown) built-in a lower cup 32, which is one component of the rotating cup 31. The annular member 27a is attached to the rotary shaft 22 and rotatable about the axis of rotation AX together with the rotary shaft 22. More particularly, the rotary shaft 22 includes a flange part 22a protruding radially outward at a position right below the spin chuck 21 as shown in FIG. 6. The annular member 27a is arranged concentrically with respect to the flange part 22a, and coupled and fixed by an unillustrated bolt or the like.

A plurality of spin chuck side magnets are arranged radially and at equal angular intervals (10° in the present embodiment) with the axis of rotation AX as a center on an outer peripheral edge part of the annular member 27a. In the present embodiment, an N-pole and an S-pole are respectively arranged on an outer side and an inner side of one of the two spin chuck side magnets adjacent to each other, and an S-pole and an N-pole are respectively arranged on an outer side and an inner side of the other magnet.

Similarly to these spin chuck side magnets, a plurality of cup side magnets are arranged radially and at equal angular intervals with the axis of rotation AX as a center. These cup side magnets are built in the lower cup 32. The lower cup 32 is a constituent component of the scattering preventing mechanism 3 to be described next and has an annular shape. That is, the lower cup 32 has an inner peripheral surface capable of facing the outer peripheral surface of the annular member 27a. An inner diameter of this inner peripheral surface is larger than an outer diameter of the annular member 27a. The lower cup 32 is arranged concentrically with the rotary shaft 22 and the annular member 27a while this inner peripheral surface is separated from the outer peripheral surface of the annular member 27a by a predetermined distance (=(the inner diameter−the outer diameter)/2) and facing the outer peripheral surface of the annular member 27a. Engaging pins 35 and coupling magnets 36 are provided on the upper surface of the outer peripheral edge of the lower cup 32, the upper cup 33 is coupled to the lower cup 32 by these, and this coupled body functions as the rotating cup 31.

The lower cup 32 is supported rotatably about the axis of rotation AX on the upper surface of the base member 17 while being kept in the above arranged state by a bearing not shown in figures. The plurality of cup side magnets are arranged radially and at equal angular intervals with the axis of rotation AX as a center on an inner peripheral edge part of this lower cup 32. Further, two cup side magnets adjacent to each other are arranged similarly to the spin chuck side magnets. That is, an N-pole and an S-pole are respectively arranged on an outer side and an inner side of one magnet, and an S-pole and an N-pole are respectively arranged on an outer side and an inner side of the other magnet.

In the power transmitter 27 thus configured, if the annular member 27a is rotated together with the rotary shaft 22 by the motor 23, the lower cup 32 rotates in the same direction as the annular member 27a while maintaining an air gap GPa (gap between the annular member 27a and the lower cup 32) by the action of magnetic forces between the spin chuck side magnets and the cup side magnets. In this way, the rotating cup 31 rotates about the axis of rotation AX. That is, the rotating cup 31 rotates in the same direction as and in synchronization with the substrate W.

The scattering preventing mechanism 3 includes the rotating cup 31 rotatable about the axis of rotation AX while surrounding the outer periphery of the substrate W held on the spin chuck 21 and a fixed cup 34 fixedly provided to surround the rotating cup 31. The rotating cup 31 is provided rotatably about the axis of rotation AX while surrounding the outer periphery of the rotating substrate W by the upper cup 33 being coupled to the lower cup 32.

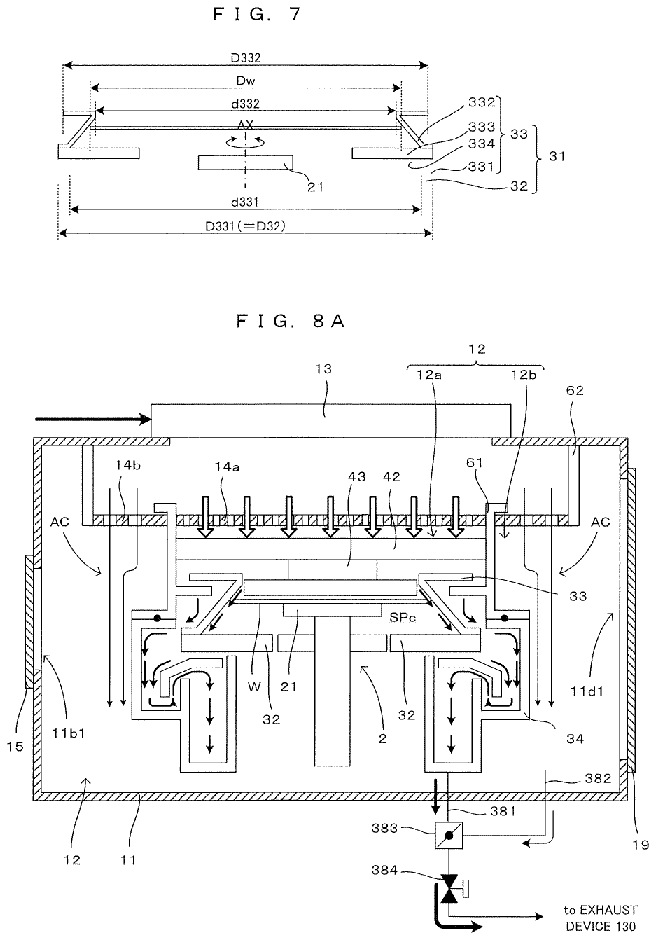

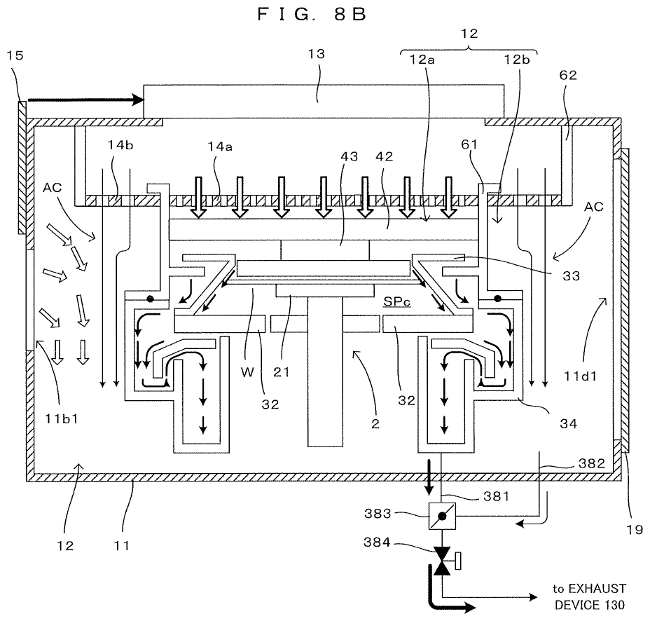

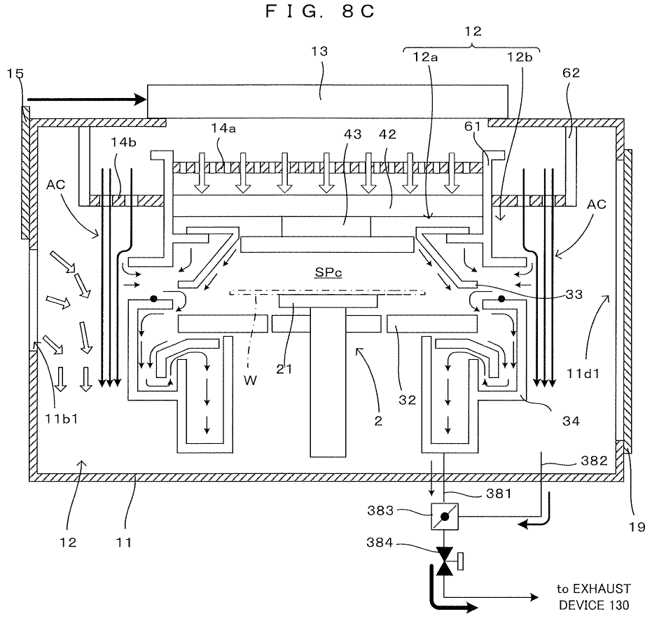

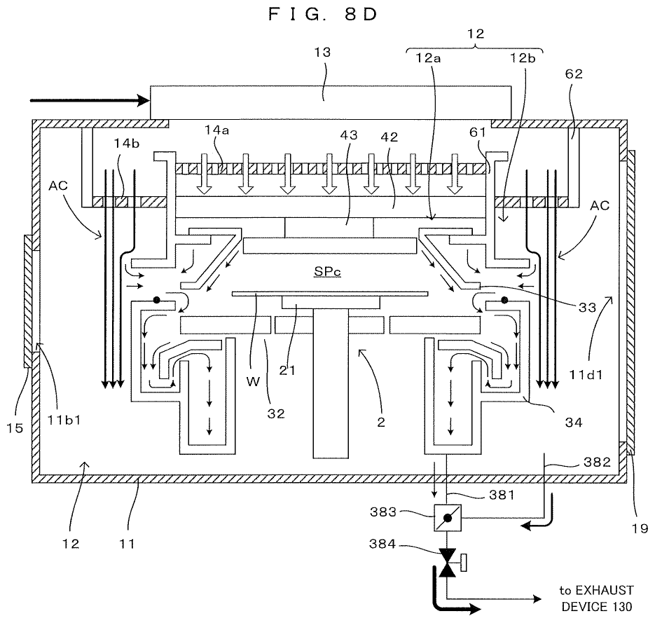

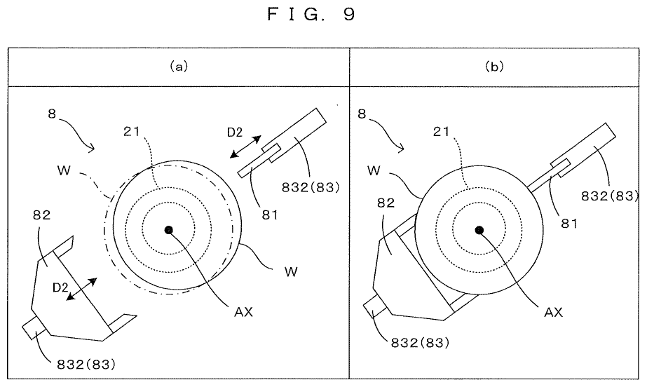

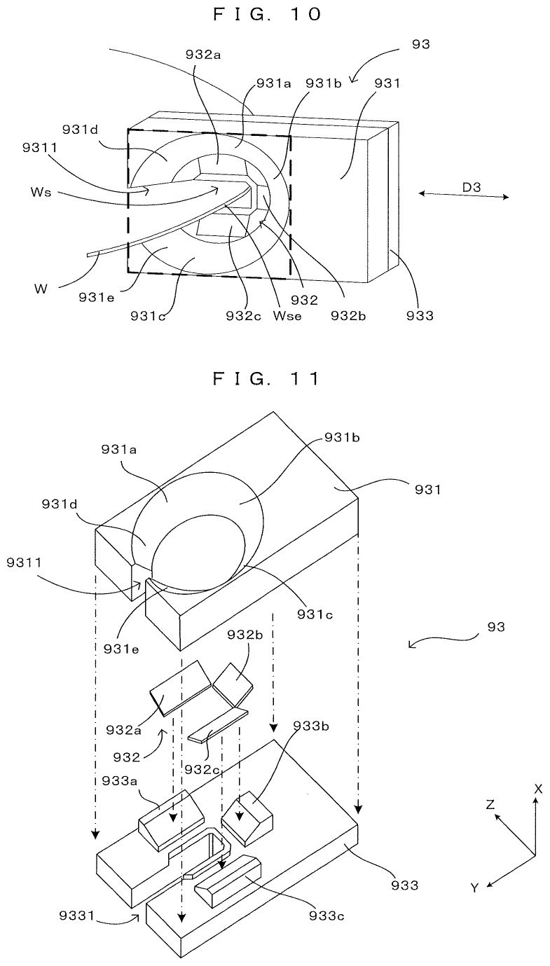

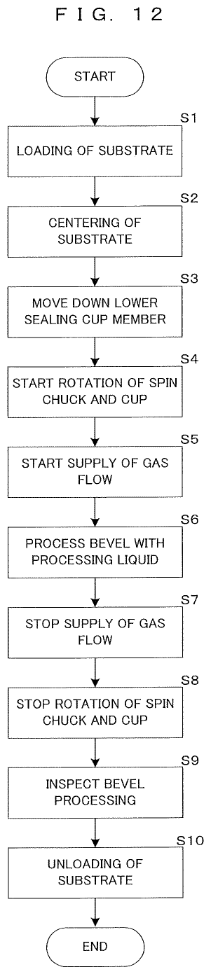

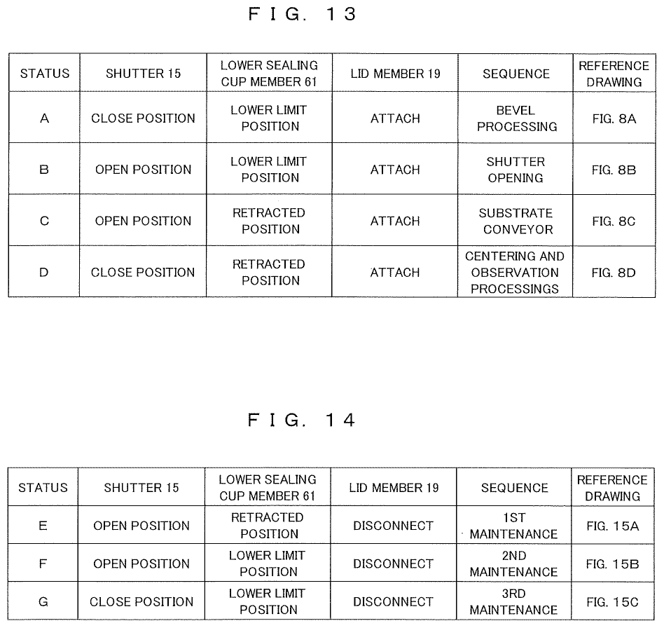

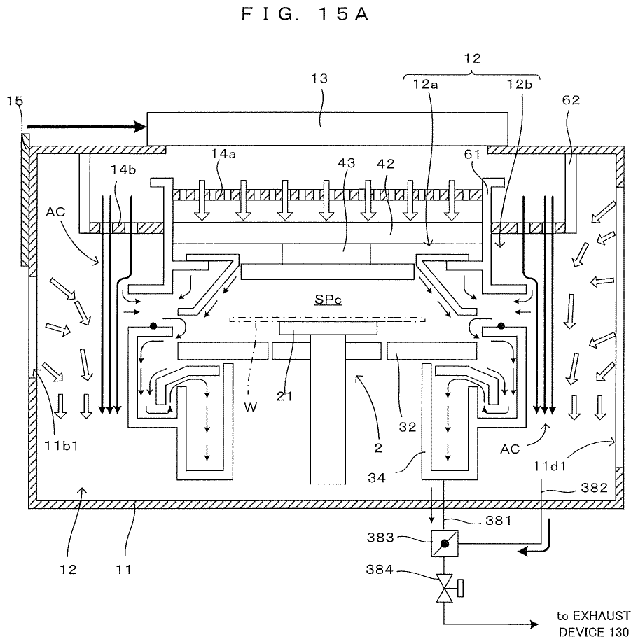

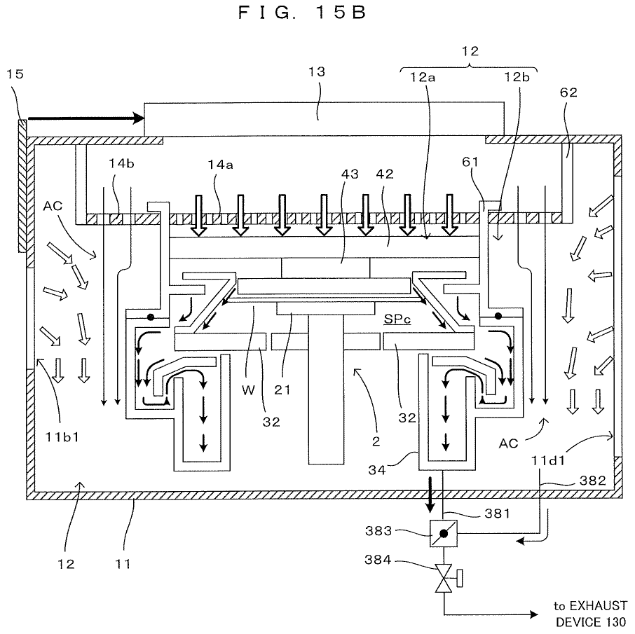

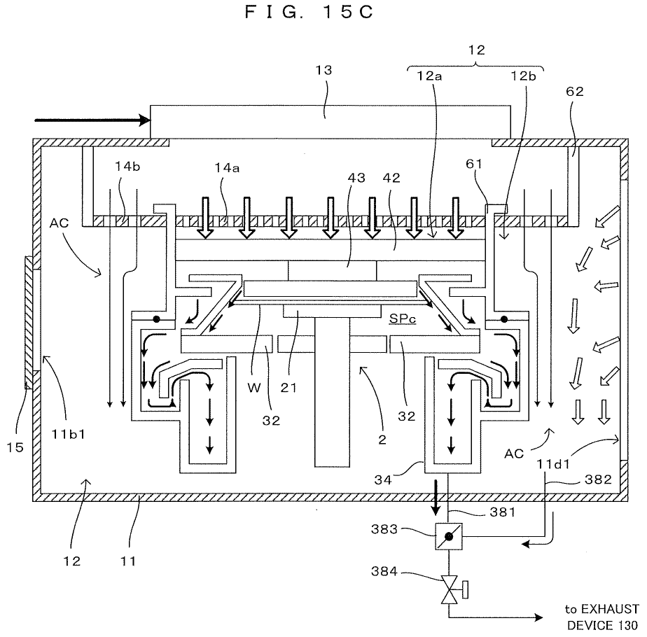

FIG. 7 is a diagram showing a dimensional relationship of the substrate held on the spin chuck and the rotating cup. FIG. 8A is a diagram schematically showing a status in each part of the apparatus during the bevel processing. FIG. 8B is a diagram schematically showing a status in each part of the apparatus during shutter opening processing. FIG. 8C is a diagram schematically showing a status in each part of the apparatus during substrate conveyance. FIG. 8D is a diagram schematically showing a status in each part of the apparatus during centering processing and observation processing. Regarding symbols representing an on/off valve in FIGS. 8A to 8D (and in FIGS. 15A to 15C referred to later), the valve with black triangles shows that the valve is opened, and the valve with white triangles shows that the valve is closed. The lower cup 32 has an annular shape. The lower cup 32 has an outer diameter larger than that of the substrate W and is arranged rotatably about the axis of rotation AX while radially protruding from the substrate W held on the spin chuck 21 in a plan view vertically from above. In this protruding region, i.e. an upper surface peripheral edge part 321 of the lower cup 32, the engaging pins 35 standing vertically upward and the flat plate-like lower magnets 36 are alternately mounted along a circumferential direction. A total of three engaging pins 35 are mounted, and a total of three lower magnets 36 are mounted. These engaging pins (not shown) and lower magnets (not shown) are arranged radially and at equal angular intervals with the axis of rotation AX as a center.

On the other hand, as shown in FIGS. 3, 4 and 7, the upper cup 33 includes a lower annular part 331, an upper annular part 332 and an inclined part 333 coupling these. An outer diameter D331 of the lower annular part 331 is equal to an outer diameter D32 of the lower cup 32 and the lower annular part 331 is located vertically above the peripheral edge part 321 of the lower cup 32. Recesses 335 open downward are provided to be fittable to tip parts of the engaging pins 35 in regions vertically above the engaging pins 35 on the lower surface of the lower annular part 331. Further, upper magnets 37 are mounted in regions vertically above the lower magnets 36. Thus, the upper cup 33 is engageable with and disengageable from the lower cup 32 with the recesses 335 and the upper magnets 37 respectively facing the engaging pins 35 and the lower magnets 36.

The upper cup 33 is movable up and down along the vertical direction by the elevating mechanism 7. If the upper cup 33 is moved up by the elevating mechanism 7, a conveyance space for carrying in and out the substrate W is formed between the upper cup 33 and the lower cup 32 in the vertical direction. On the other hand, if the upper cup 33 is moved down by the elevating mechanism 7, the recesses 335 are fit to cover the tip parts of the engaging pins 35 and the upper cup 33 is positioned in a horizontal direction with respect to the lower cup 32. Further, the upper magnets 37 approach the lower magnets 36, and the positioned upper and lower cups 33, 32 are bonded to each other by attraction forces generated between the both magnets. In this way, as shown in a partial enlarged view of FIG. 5 and FIG. 8, the upper and lower cups 33, 32 are integrated in the vertical direction with a gap GPc extending in the horizontal direction formed. The rotating cup 31 is rotatable about the axis of rotation AX while forming the gap GPc.

In the rotating cup 31, as shown in FIG. 7, an outer diameter D332 of the upper annular part 332 is slightly smaller than the outer diameter D331 of the lower annular part 331 as shown in FIG. 7. Further, if diameters d331, d332 of the inner peripheral surfaces of the lower and upper annular parts 331, 332 are compared, the lower annular part 331 is larger than the upper annular part 332 and the inner peripheral surface of the upper annular part 332 is located inside the inner peripheral surface of the lower annular part 331 in a plan view vertically from above. The inner peripheral surface of the upper annular part 332 and that of the lower annular part 331 are coupled by the inclined part 333 over the entire circumference of the upper cup 33. Thus, the inner peripheral surface of the inclined part 333, i.e. a surface surrounding the substrate W, serves as an inclined surface 334. That is, as shown in FIG. 8, the inclined part 333 can collect liquid droplets scattered from the substrate W by surrounding the outer periphery of the rotating substrate W, and a space surrounded by the upper and lower cups 33, 32 functions as a processing space SPc.

Moreover, the inclined part 333 facing the processing space SPc is inclined upwardly of the peripheral edge part of the substrate W from the lower annular part 331. Thus, the liquid droplets collected by the inclined part 333 can flow to a lower end part of the upper cup 33, i.e. the lower annular part 331, along the inclined surface 334, and can be discharged to the outside of the rotating cup 31 via the gap GPc.

The fixed cup 34 is provided to surround the rotating cup 31 and forms a discharge space SPe. The fixed cup 34 includes a liquid receiving part 341 and an exhaust part 342 provided inside the liquid receiving part 341. The liquid receiving part 341 has a cup structure open to face an opening of the gap GPc on a side opposite to the substrate. That is, an internal space of the liquid receiving part 341 functions as the discharge space SPe and communicates with the processing space SPc via the gap GPc. Therefore, the liquid droplets collected by the rotating cup 31 are guided into the discharge space SPe via the gap GPc together with gas components. Then, the liquid droplets are collected in a bottom part of the liquid receiving part 341 and discharged from the fixed cup 34.

On the other hand, the gas components are collected into the exhaust part 342. This exhaust part 342 is partitioned from the liquid receiving part 341 via a partition wall 343. Further, a gas guiding part 344 is arranged above the partition wall 343. The gas guiding part 344 extends from a position right above the partition wall 343 into the discharge space SPe and the exhaust part 342, thereby forming a flow passage for the gas components having a labyrinth structure by covering the partition wall 343 from above. Accordingly, the gas components, out of a fluid flowing into the liquid receiving part 341, are collected in the exhaust part 342 by way of the flow passage. The exhaust part 342 is connected to the exhaust device 130 via a first exhaust pipe 381, a damper 383, and an on/off valve 384. The internal space 12 of the chamber 11 is connected to the exhaust device 130 via a second exhaust pipe 382, the damper 383, and the on/off valve 384. Thus, by adjusting a degree of opening of the damper 383 in response to a command from an exhaust controller 10G with the on/off valve 384 opened, it becomes possible to change a ratio between an exhaust flow rate of exhaust from the processing space SPc surrounded by the upper cup 33 and the lower cup 32 (hereinafter called a “cup exhaust flow rate”) and an exhaust flow rate of exhaust from a space in the internal space 12 of the chamber 11 and other than the processing space SPc (hereinafter called a “chamber exhaust flow rate”). More specifically, when the lower sealing cup member 61 is positioned at a lower limit position right above the liquid receiving part 341 of the scattering preventing mechanism 3 to cause the atmosphere separating mechanism 6 to perform atmosphere separation, the exhaust controller 10G controls the damper 383 in such a manner that the cup exhaust flow rate becomes greater than the chamber exhaust flow rate. By doing so, the gas components in the exhaust part 342 are exhausted efficiently. Furthermore, a pressure in the discharge space SPe is adjusted. As an example, a pressure in the discharge space SPe becomes lower than a pressure in the processing space SPc. As a result, liquid droplets in the processing space SPc can be efficiently drawn into the discharge space SPe and movements of the liquid droplets from the processing space SPc can be promoted. On the other hand, when the lower sealing cup member 61 is positioned vertically above the lower limit position to release formation of the atmosphere separation, the exhaust controller 10G controls the damper 383 in such a manner that the chamber exhaust flow rate becomes greater than the cup exhaust flow rate. As a result, the flow rate of the cleaned air forming an air curtain configured along the lower sealing cup member 61 is increased as described later, making it possible to suppress incoming flow of a foreign matter.

In the present embodiment, for implementation of the maintenance processing on the substrate processing apparatus 1, the exhaust controller 10G closes the on/off valve 384. This disconnects the substrate processing apparatus 1 and the exhaust device 130 from each other during the maintenance processing, making it possible to reliably prevent influence on the operation of the other substrate processing apparatus 1. Specifically, it is possible to perform the maintenance processing on the pertinent substrate processing apparatus 1 while the other substrate processing apparatus 1 works as usual. As a result, it is possible to enhance the availability factor of the substrate processing system 100.

The upper surface protecting/heating mechanism 4 includes a shielding plate 41 arranged above the upper surface Wf of the substrate W held on the spin chuck 21. This shielding plate 41 includes a disk part 42 held in a horizontal posture. The disk part 42 has a built-in heater 421 drive-controlled by a heater driver 422. This disk part 42 has a diameter slightly shorter than that of the substrate W. The disk part 42 is so supported by a support member 43 that the lower surface of the disk part 42 covers a surface region excluding the peripheral edge part Ws, out of the upper surface Wf of the substrate W, from above. Note that reference sign 44 in FIG. 5 denotes a cut provided in a peripheral edge part of the disk part 42, and this cut is provided to prevent interference with processing liquid discharge nozzles included in the processing mechanism 5. The cut 44 is opened radially outward.

A lower end part of the support member 43 is mounted in a central part of the disk part 42. The cylindrical through hole is formed to vertically penetrate through the support member 43 and the disk part 42. Further, a center nozzle 45 is vertically inserted into this through hole. As shown in FIG. 3, the heated gas supplier 47 is connected to this center nozzle 45 via a pipe (not shown). The heated gas supplier 47 heats a nitrogen gas at a normal temperature supplied from utilities of the factory in which the substrate processing system 100 is installed and supplies the heated gas to the center nozzle 45 at a flow rate and a timing corresponding to a heated gas supply command from the control unit 10.

The nitrogen gas (hereinafter, referred to as a “heated gas”) heated in this way is fed under pressure toward the center nozzle 45 and discharged from the center nozzle 45. By supplying the heated gas with the disk part 42 positioned at a processing position near the substrate W held on the spin chuck 21, the heated gas flows toward a peripheral edge part from a central part of a space sandwiched between the upper surface Wf of the substrate W and the disk part 42 including the built-in heater. In this way, an atmosphere around the substrate W can be suppressed from reaching the upper surface Wf of the substrate W. As a result, the liquid droplets included in the atmosphere can be effectively prevented from getting in the space SPa sandwiched between the substrate W and the disk part 42. Further, the upper surface Wf is entirely heated by heating of the heater 421 and the heated gas, whereby an in-plane temperature of the substrate W can be made uniform. In this way, the warping of the substrate W can be suppressed and a liquid landing position of the processing liquid can be stabilized.

As shown in FIG. 3, an upper end part of the support member 43 is fixed to a beam member 49 extending along the first virtual horizontal line VL1. This beam member 49 is connected to the elevating mechanism 7 installed on the upper surface of the base member 17 and moved up and down by the elevating mechanism 7 in response to a command from the control unit 10. For example, in FIG. 3, the beam member 49 is positioned below, whereby the disk part 42 coupled to the beam member 49 is located at the processing position via the support member 43. On the other hand, if the elevating mechanism 7 moves up the beam member 49 in response to a move-up command from the control unit 10, the beam member 49, the support member 43 and the disk part 42 integrally move upward and the upper cup 33 is also linked, separated from the lower cup 32 and moves up. In this way, the upper cup 33 and the disk part 42 are spaced wider apart from the spin chuck 21 and the substrate W can be carried to and from the spin chuck 21.

The processing mechanism 5 includes processing liquid discharge nozzles 51F (see FIG. 5) arranged on the upper surface side of the substrate W, processing liquid discharge nozzles 51B (see FIG. 3) arranged on the lower surface side of the substrate W and processing liquid suppliers 52 for supplying the processing liquid to the processing liquid discharge nozzles 51F, 51B. The lower processing liquid discharge nozzles 51F on the upper surface side and the processing liquid discharge nozzles 51B on the lower surface side are respectively referred to as “upper surface nozzles 51F” and “lower surface nozzles 51B” to be distinguished. Further, two processing liquid suppliers 52 shown in FIG. 3 are identical.

In the present embodiment, three upper surface nozzles 51F are provided, and the processing liquid supplier 52 is connected to those. Further, the processing liquid supplier 52 is configured to be capable of supplying SC1, DHF and functional water (CO2 water or the like) as the processing liquids, and the SC1, DHF and functional water can be respectively independently discharged from the three upper surface nozzles 51F.

Each of the upper surface nozzles 51F is provided with a discharge port (not shown) for discharging the processing liquid in a lower surface of a tip thereof. Then, as shown in an enlarged view in FIG. 5, with the respective discharge ports facing the peripheral edge part of the upper surface Wf of the substrate W, lower parts of a plurality of (three in the present embodiment) upper surface nozzles 51F are arranged in the cut 44 (see FIG. 5) of the disk part 42 and upper parts of the upper surface nozzles 51F are mounted movably to a nozzle holder 53 in a radial direction D1. This nozzle holder 53 is connected to a nozzle mover 54.

The nozzle mover 54 is attached to an upper end part of a lifter (not shown) of an elevator 713 described later while holding the nozzle head 56 (=the upper surface nozzle 51F+the nozzle holder 53). For this reason, in response to an up-and-down command from the control unit 10, the lifter 713a expands and contracts in the vertical direction and accordingly the nozzle mover 54 and the nozzle head 56 move in the vertical direction Z.

The nozzle mover 54 has a linear actuator and moves nozzle head 56. As a result, the upper surface nozzle 51F attached to the nozzle head 56 is positioned in the radial direction D1. The upper surface nozzle 51F is accurately positioned at a bevel processing position.

The discharge ports (not shown) of the upper surface nozzle 51F positioned at this bevel processing position are facing the peripheral edge part of the upper surface Wf of the substrate W. If the processing liquid supplier 52 supplies the processing liquid corresponding to a supply command, out of three kinds of processing liquids, to the upper surface nozzle 51F for the processing liquid in response to the supply command from the control unit 10, the processing liquid is discharged from the upper surface nozzle 51F to a predetermined position from the edge surface of the substrate W.

Further, to part of the constituent components of the nozzle mover 54, a lower sealing cup member 61 of the atmosphere separating mechanism 6 is detachably fixed. Specifically, when the bevel processing is performed, the upper surface nozzle 51F and the nozzle holder 53 are integrated with the lower sealing cup member 61 with the nozzle mover 54 interposed therebetween and moved up and down in the vertical direction Z together with the lower sealing cup member 61 by the elevating mechanism 7.

In the present embodiment, the lower surface nozzles 51B and a nozzle support 57 are provided below the substrate W held on the spin chuck 21 to discharge the processing liquid toward the peripheral edge part of the lower surface Wb of the substrate W. The nozzle support 57 includes a thin hollow cylindrical part 571 extending in the vertical direction and a flange part 572 having an annular shape and bent to expand radially outward in an upper end part of the hollow cylindrical part 571. The hollow cylindrical part 571 is shaped to be loosely insertable into the air gap GPa formed between the annular member 27a and the lower cup 32. As shown in FIG. 3, the nozzle support 57 is so fixedly arranged that the hollow cylindrical part 571 is loosely inserted in the air gap GPa and the flange part 572 is located between the substrate W supported on the spin chuck 21 and the lower cup 32. Three lower surface nozzles 51B are mounted on a peripheral edge part of the upper surface of the flange part 572. Each lower surface nozzle 51B includes a discharge port (not shown) open toward the peripheral edge part of the lower surface Wb of the substrate W and can discharge the processing liquid supplied from the processing liquid supplier 52.

The bevel processing for the peripheral edge part of the substrate W is performed by the processing liquids discharged from these upper surface nozzles 51F and lower surface nozzles 51B. Further, on the lower surface side of the substrate W, the flange part 572 is extended to the vicinity of the peripheral edge part Ws. Thus, the nitrogen gas supplied to the lower surface side via the pipe 28 flows into the processing space S. As a result, a backflow of the liquid droplets from the processing space SPc to the substrate W is effectively suppressed.

The atmosphere separating mechanism 6 includes the lower sealing cup member 61 and an upper sealing cup member 62. Both of the upper and lower sealing cup members 61, 62 have a tube shape open in the vertical direction. Inner diameters of those are larger than an outer diameter of the rotating cup 31, and the atmosphere separating mechanism 6 is arranged to completely surround the spin chuck 21, the substrate W held on the spin chuck 21, the rotating cup 31 and the upper surface protecting/heating mechanism 4 from above. More particularly, as shown in FIG. 3, the upper sealing cup member 62 is fixedly attached to the ceiling wall 11f so that the upper opening thereof covers the opening 11f1 of the ceiling wall 11f from below.

The upper sealing cup member 62 has a lower end part where the flow straightening member 14b having an annular shape is attached along an inner peripheral surface of the upper sealing cup member 62. The lower sealing cup member 61 is provided movably in the vertical direction Z with an outer peripheral surface of the lower sealing cup member 61 overlapping the inner peripheral surface of the upper sealing cup member 62 in the vertical direction Z.

A lower end part of the lower sealing cup member 61 includes a flange part 612 bent outwardly and having an annular shape. This flange part 612 overlaps an upper end part of the fixed cup 34 (upper end part of the liquid receiving part 341) in a plan view vertically from above. Thus, at the lower limit position, the flange part 612 of the lower sealing cup member 61 is locked by the fixed cup 34 via an O-ring 64 as shown in the enlarged view of FIG. 5. In this way, the lower sealing cup member 61 and the fixed cup 34 are connected in the vertical direction, and a sealed space 12a is formed by the upper sealing cup member 62, the lower sealing cup member 61 and the fixed cup 34. The bevel processing on the substrate W can be performed in this sealed space SPs. That is, by positioning the lower sealing cup member 61 at the lower limit position, the sealed space 12a is separated from an outside space 12b of the sealed space 12a (atmosphere separation). Therefore, the bevel processing can be stably performed without being influenced by an outside atmosphere. Further, the processing liquids are used to perform the bevel processing. The processing liquids can be reliably prevented from leaking from the sealed space 12a to the outside space 12b. Thus, a degree of freedom in selecting/designing components to be arranged in the outside space 12b is enhanced.

The lower sealing cup member 61 is also configured to be movable vertically upward. The nozzle head 56 (=upper surface nozzles 51F+nozzle holder 53) is fixed to an intermediate part of the lower sealing cup member 61 in the vertical direction via the the head support member 547 of the nozzle mover 54 as described above. Besides this, as shown in FIGS. 3 and 5, the upper surface protecting/heating mechanism 4 is fixed to an intermediate part of the lower sealing cup member 61 via the beam member 49. That is, as shown in FIG. 5, the lower sealing cup member 61 is connected to one end part of the beam member 49, the other end part of the beam member 49 and the head support member 547 of the nozzle mover 54 at three positions mutually different in the circumferential direction. By moving up and down the one end part of the beam member 49, the other end part of the beam member 49 and the support member 547 by the elevating mechanism 7, the lower sealing cup member 61 is also moved up and down accordingly.

As shown in FIGS. 3 and 5, a plurality of (four) projections 613 are provided to project inward as engaging parts engageable with the upper cup 33 on the inner peripheral surface of the lower sealing cup member 61. Each projection 613 extends to a space below the upper annular part 332 of the upper cup 33. Further, each projection 613 is so mounted to be separated downward from the upper annular part 332 of the upper cup 33 with the lower sealing cup member 61 positioned at the lower limit position. By an upward movement of the lower sealing cup member 61, each projection 613 is engageable with the upper annular part 332 from below. The lower sealing cup member 61 moves further upward also after this engagement, whereby the upper cup 33 can be separated from the lower cup 32.

In the present embodiment, after the lower sealing cup member 61 starts to be moved up together with the upper surface protecting/heating mechanism 4 and the nozzle head 56 by the elevating mechanism 7, the upper cup 33 also moves up. In this way, the upper cup 33, the upper surface protecting/heating mechanism 4, and the nozzle head 56 are separated upward from the spin chuck 21. By the movement of the lower sealing cup member 61 to a retracted position, a space for implementations of various types of processing is formed. This space is a conveyance space for allowing the hand of the substrate conveyor robot 111 to access the spin chuck 21, for example. The substrate W can be loaded onto the spin chuck 21 and unloaded from the spin chuck 21 via this conveyance space. This space is also used during the centering processing by the centering mechanism 8 and the observation processing by the substrate observing mechanism 9.

The inside flow straightening member 14a and the outside flow straightening member 14b are respectively attached to the lower sealing cup member 61 and the upper sealing cup member 62 having the foregoing configurations. As shown in FIGS. 3 and 5, the inside flow straightening member 14a is composed of a punching plate perforated with a multitude of through holes 14a1 having a relatively small diameter and distributed uniformly, and is attached to the inner peripheral surface of the lower sealing cup member 61 in such a manner as to close an upper opening of the lower sealing cup member 61. Thus, the flow of the cleaned air supplied from the fan filter unit 13 is straightened by the inside flow straightening member 14a and is then supplied to the sealed space 12a. The inside flow straightening member 14a is attached to the lower sealing cup member 61. Meanwhile, the outside flow straightening member 14b is composed of a punching plate prepared by perforating a plate having an annular shape (one example of a “disk-like plate” of the present invention) with through holes 14b1 having a larger inner diameter than the through holes 14a1, and is attached to the upper sealing cup member 62 while being position between the outer peripheral surface of the lower sealing cup member 61 and the inner peripheral surface of the upper sealing cup member 62. Thus, after the flow of the cleaned air passing between the lower sealing cup member 61 and the upper sealing cup member 62 is straightened by the outside flow straightening member 14b, the cleaned air flows downward along an outer side surface of the lower sealing cup member 61, as shown in FIGS. 8A to 8D, for example. By doing so, the scattering preventing mechanism 3 and the atmosphere separating mechanism 6 are surrounded by an air curtain AC. The flow rate of the cleaned air forming the air curtain AC is comparatively small when the lower sealing cup member 61 is at the lower limit position. Conversely, when the lower sealing cup member 61 moves vertically upward from the lower limit fixed position, namely, moves to the retracted position, this flow rate becomes comparatively large. Such change in the flow rate is generated for reason and achieves effects to be described later in connection with the operation of the substrate processing apparatus 1.

An upper end part of the lower sealing cup member 61 includes a flange part 611 bent to expand outward and having an annular shape. The flange part 611 overlaps the flange part 621 in a plan view vertically from above. Thus, if the lower sealing cup member 61 moves down, as shown in the partial enlarged view of FIG. 6, the flange part 611 of the lower sealing cup member 61 becomes locked by a part of the outside flow straightening member 14b. In this way, the lower sealing cup member 61 is positioned at the above-described lower limit position

The elevating mechanism 7 includes two elevation drivers 71, 72. In the elevation driver 71, a first elevation motor (not shown) is attached to a first elevation mounting portion 173 (FIG. 4) of the base member 17. The first elevation motor generates a rotational force by operating in response to a drive command from the control unit 10. Two elevators 712, 713 are coupled to this first elevation motor 711. The elevators 712, 713 simultaneously receive the rotational force from the first elevation motor 711. Then, the elevator 712 moves up and down a support member 491 supporting the one end part of the beam member 49 along the vertical direction Z according to a rotation amount of the first elevation motor 711. Further, the elevator 713 moves up and down the support member 54 supporting the nozzle head 56 along the vertical direction Z according to the rotation amount of the first elevation motor.

In the elevation driver 72, a second elevation motor (not shown) is attached to a second elevation mounting portion 174 (FIG. 4) of the base member 17. An elevator 722 is coupled with the second elevation motor. The second elevation motor generates a rotational force by operating in response to a drive command from the control unit 10 and gives the generated rotational force to the elevator 722. The elevator 722 moves up and down a support member 492 supporting the other end part of the beam member 49 along the vertical direction Z according to the amount of rotation of the second elevation motor.

The elevation drivers 71, 72 synchronously and vertically move the support members 491, 492 and 54 respectively fixed to the side surface of the lower sealing cup member 61 at three positions mutually different in the circumferential direction. Therefore, the upper surface protecting/heating mechanism 4, the nozzle head 56 and the lower sealing cup member 61 can be stably moved up and down. Further, the upper cup 33 can be also stably moved up and down as the lower sealing cup member 61 is moved up and down.

FIG. 9 is a diagram schematically showing the configuration and operation of the centering mechanism. The centering mechanism 8 performs centering processing while the suction by the pump 26 is stopped (i.e. while the substrate W is horizontally movable on the upper surface of the spin chuck 21). By this centering processing, the eccentricity of the substrate W (with respect to the spin chuck 21) is eliminated and a center of the substrate W coincides with the axis of rotation AX. As shown in FIGS. 5 and 9, the centering mechanism 8 has a single contact part 81 disposed on a side of the conveyance opening 11b1 (on the right side of FIG. 9) with respect to the axis of rotation AX in a contact movement direction D2 inclined at about 40° with respect to the first virtual horizontal line VL1, a multi-contact part 82 disposed on a side of the maintenance opening 11d1 (on the left side of FIG. 9), and a centering driver 83 for moving the single contact part 81 and the multi-contact part 82 in the contact movement direction D2.

The single contact part 81 has a shape extending in parallel to the contact movement direction D2 and is finished to be contactable with the end surface of the substrate W on the spin chuck 21 at a tip part on the side of the spin chuck 21. On the other hand, the multi-contact part 82 has a substantial Y shape in a plan view vertically from above and is finished to be contactable with the end surface of the substrate W on the spin chuck 21 at each tip part of a bifurcated portion on the side of the spin chuck 21. The single contact part 81 and the multi-contact part 82 are movable in the contact movement direction D2.

The centering driver 83 has a single mover 831 for moving the single contact part 81 in the contact movement direction D2 and a multi-mover 832 for moving the multi-contact part 82 in the contact movement direction D2. The single mover 831 is mounted on a single moving attachment portion 175 (FIG. 4) of the base member 17 and the multi-mover 832 is mounted on a multi-moving attachment portion 176 (FIG. 4) of the base member 17. While the centering processing of the substrate W is not performed, as shown in FIG. 5 and the column (a) of FIG. 9, the centering driver 83 positions the single contact part 81 and the multi-contact part 82 away from the spin chuck 21. For this reason, the single contact part 81 and the multi-contact part 82 are away from the conveyance path TP, and it is thereby possible to effectively prevent interference of the single contact part 81 and the multi-contact part 82 with the substrate W loaded into or unloaded from the chamber 11.

On the other hand, when the centering processing of the substrate W is performed, in response to a centering command from the control unit 10, the single mover 831 move the single contact part 81 toward the axis of rotation AX and the multi-mover 832 moves the multi-contact part 82 toward the axis of rotation AX. The center of the substrate W thereby coincides with the axis of rotation AX, as shown in the column (b) of FIG. 9.

FIG. 10 is a perspective view showing an observation head of the substrate observing mechanism. FIG. 11 is an exploded assembly perspective view of the observation head shown in FIG. 10. The substrate observing mechanism 9 has a light source part 91, an image pickup part 92, an observation head 93, and an observation head driver 94. The light source part 91 and the image pickup part 92 are arranged in parallel at an optical component attachment position 177 (FIG. 4) of the base member 17. In response to a lighting command from the control unit 10, the light source part 91 emits illumination light toward an observation position. This observation position is a position corresponding to the peripheral edge part Ws of the substrate W, which corresponds to a position at which the observation head 93 is positioned in FIG. 10.

The observation head 93 is reciprocally movable between the observation position and a separation position away from the observation position outside in a radial direction of the substrate W. The observation head driver 94 is connected to the observation head 93. The observation head driver 94 is attached to the base member 17 at a head driving position 178 (FIG. 4) of the base member 17. In response to a head moving command from the control unit 10, the observation head driver 94 causes the observation head 93 to reciprocally move in a head movement direction D3 inclined at about 10° with respect to the first virtual horizontal line VL1. More specifically, while observation processing of the substrate W is not performed, the observation head driver 94 causes the observation head 93 to move to the retracted position, to be positioned. For this reason, the observation head 93 is away from the conveyance path TP, and it is thereby possible to effectively prevent interference of the observation head 93 with the substrate W loaded into or unloaded from the chamber 11. On the other hand, when the observation processing of the substrate W is performed, in response to a substrate observing command from the control unit 10, the observation head driver 94 causes the observation head 93 to move to the observation position.

As shown in FIGS. 10 and 11, the observation head 93 has a diffused lighting part 931 having five diffusion surfaces 931ato 931d, a guide 932 consisting of three mirror members 932a to 932c, and a holder 933.

The holder 933 is composed of, for example, PEEK (polyetheretherketone), and as shown in FIGS. 10 and 11, is provided with a cut 9331 at an end part on a side of the substrate W. The size of the cut 9331 in the vertical direction is wider than the thickness of the substrate W, and as shown in FIG. 10, when the observation head 93 is positioned at the observation position, the cut 9331 enters the peripheral edge part Ws of the substrate W and even an area inside in the radial direction from the peripheral edge part Ws. Further, the holder 933 is finished to have a shape which can be engaged with the diffused lighting part 931. Moreover, the holder 933 has mirror supporters 933a to 933c for supporting the mirror members 932a to 932c from a back-surface side, respectively. For this reason, the diffused lighting part 931 and the holder 933 are engaged with each other, to be thereby integrated while holding the mirror members 932a to 932c.

The diffused lighting part 931 is composed of, for example, PTFE (polytetrafluoroethylene). As shown in FIGS. 10 and 11, the diffused lighting part 931 has a plate shape extending in the horizontal direction and is provided with a cut 9311 at an end part on a side of the substrate W, like the holder 933. As shown in FIG. 10, the cut 9311 has an inverted C shape viewed from a circumferential direction of the substrate W. Further, in the diffused lighting part 931, an inclined surface is provided along the cut 9311. The inclined surface is a tapered surface which is finished to be inclined toward a direction (horizontal direction orthogonal to the direction D3) in which the illumination light goes as it gets closer to the cut 9311. Especially, a vertical upper area of the cut 9311, a side area thereof, and a vertical lower area thereof in this tapered surface serve as the diffusion surfaces 931a to 931c, respectively. Further, in the cut 9311, areas positioned on a side of axis of rotation AX of the mirror members 932a and 932c serve as the diffusion surfaces 931d and 931e, respectively.

When the observation head 93 having such a configuration is positioned at the observation position, the diffusion surfaces 931a to 931e are positioned in a lighting area (indicated by a thick broken-line area in FIG. 10) formed by the light source part 91. When the light source part 91 is lighted in response to the lighting command from the control unit 10 in this positioning state, the illumination light is emitted to the lighting area. At that time, the diffusion surfaces 931a to 931e diffusedly reflect the illumination light and illuminate the peripheral edge part Ws of the substrate W and an adjacent area thereof from various directions. Herein, among the illumination light, part of upper-surface diffused light that goes toward the upper surface of the substrate W including the peripheral edge part Ws is reflected by the upper surface of the peripheral edge part Ws and the adjacent area of the peripheral edge part Ws (an upper-surface area adjacent to the peripheral edge part Ws inside in the radial direction). This reflected light is reflected by a reflection surface of the mirror member 932a and then guided to the image pickup part 92. Further, among the illumination light, part of lower-surface diffused light that goes toward the lower surface of the substrate W including the peripheral edge part Ws is reflected by the lower surface of the peripheral edge part Ws and the adjacent area of the peripheral edge part Ws (a lower-surface area adjacent to the peripheral edge part Ws inside in the radial direction). This reflected light is reflected by a reflection surface of the mirror member 932c and then guided to the image pickup part 92. Among the illumination light, part of side-surface diffused light that goes toward the side surface (end surface) Wse of the substrate W is reflected by the side surface Wse of the substrate W. This reflected light is reflected by a reflection surface of the mirror member 62b and then guided to the image pickup part 92.

The image pickup part 92 has an observation lens system consisting of object-side telecentric lenses and a CMOS camera. Therefore, among the reflected light guided from the observation head 93, only rays of light in parallel to the optical axis of the observation lens system enter a sensor surface of the CMOS camera and an image of the peripheral edge part Ws of the substrate W and the adjacent area thereof is formed on the sensor surface. Thus, the image pickup part 92 images the peripheral edge part Ws of the substrate W and the adjacent area thereof and acquires an upper-surface image, a side-surface image, and a lower-surface image of the substrate W. Then, the image pickup part 92 transmits image data representing these images to the control unit 10.

As shown in FIG. 3, the control unit 10 includes an arithmetic processor 10A, a storage 10B, a reader 10C, an image processor 10D, a drive controller 10E, a communicator 10F and an exhaust controller 10G. The storage 10B is constituted by a hard disk drive or the like, and stores a program for performing the bevel processing by the substrate processing apparatus 1. This program is stored, for example, in a computer-readable recording medium RM (e.g. an optical disk, a magnetic disk, a magneto-optical disk, or the like), read from the recording medium RM by the reader 10C and saved in the storage 10B. Further, the program may be provided, for example, via an electrical communication line without being limited to provision via the recording medium RM. The image processor 10D applies various processings to an image captured by the substrate observing mechanism 9. The drive controller 10E controls each driver of the substrate processing apparatus 1. The communicator 10F conducts communication with a controller for integrally controlling each component of the substrate processing system 100 and the like. The exhaust controller 10G controls damper 383, which adjusts the ratio between cup exhaust flow and chamber exhaust flow, and on/off valve 384, which switches the connection/stop connection with the exhaust device 130.

Further, a display unit 10H (e.g. a display and the like) for displaying various pieces of information and an input unit (e.g. a keyboard, a mouse and the like) for receiving an input from an operator are connected to the control unit 10.

The arithmetic processor 10A is constituted by a computer including a CPU (=Central Processing Unit), a RAM (=Random Access Memory) and the like, and performs the bevel processing by controlling each component of the substrate processing apparatus 1 in accordance with the program stored in the storage 10B as described below. The bevel processing by the substrate processing apparatus 1 is described below with reference to FIG. 12.

FIG. 12 is a flowchart showing the bevel processing performed, as an example of a substrate processing operation, by the substrate processing apparatus shown in FIG. 3. FIG. 13 is a diagram showing a state in each part of the apparatus corresponding to each status of the substrate processing operation. The substance of the bevel processing, corresponding to one example of a “substrate processing method” of the present invention, will be described below by referring to FIGS. 8A to 8D and FIGS. 12 and 13, as appropriate.

In applying the bevel processing to the substrate W by the substrate processing apparatus 1, the arithmetic processor 10A uses the centering driver 83 to move the single mover 831 and the multi-contact part 82 to the retracted position away from the spin chuck 21 and also uses the observation head driver 94 to move the observation head 93 to a waiting position away from the spin chuck 21. Among the constituent elements arranged around the spin chuck 21, as shown in FIG. 5, the nozzle head 56, the light source part 91, the image pickup part 92, the motor 23, and the multi-contact part 82 are thereby positioned on the side of the maintenance opening (the lower side in this figure) relative to the first virtual horizontal line VL1. Further, though the single mover 831 and the observation head 93 are positioned on the side of the conveyance opening 11b1 relative to the first virtual horizontal line VL1, these constituent elements are out of a moving area of the substrate W along the conveyance path TP. This ensures that interference with the substrate W can be avoided during loading/unloading of the substrate W to/from the spin chuck 21.

Then, the arithmetic processor 10A shifts each part of the substrate processing apparatus 1 from the state shown in FIG. 8A suitable for the bevel processing (status A in FIG. 13) to the state shown in FIG. 8B where the shutter 15 is opened (status B in FIG. 13). More specifically, while atmosphere separation is formed by positioning the lower sealing cup member 61 at the lower limit position and while the maintenance opening 11d1 is kept closed by attaching the lid member 19 to the side wall 11d, the arithmetic processor 10A opens the shutter 15. In doing this, a foreign matter might flow into the chamber 11 via the opened conveyance opening 11b1. In this regard, the processing space SPc is atmosphere separated, so that a foreign matter does not flow into the processing space SPc. Furthermore, in the present embodiment, the damper 383 makes flow rate adjustment in such a manner as to realize (cup exhaust flow rate: chamber exhaust flow rate=9:1) in the statuses A and B. Thus, much of the cleaned air supplied from the fan filter unit 13 flows into the processing space SPc. Meanwhile, part of the cleaned air flows downward along the outer side surface of the lower sealing cup member 61 to form the air curtain AC. Thus, a foreign matter having flowed into the chamber 11 is discharged from the chamber 11 by the flow of the cleaned air forming the air curtain AC.

Subsequent to this shutter opening, the arithmetic processor 10A moves up the beam member 49, the support member 43, the disk part 42, the upper cup 33, and the lower sealing cup member 61 integrally, as shown in FIG. 8C. This forms the conveyance space for allowing the hand of the substrate conveyor robot 111 to access the spin chuck 21. Namely, the substrate processing apparatus 1 is brought into a status C allowing substrate conveyance, thereby completing preparation for loading the substrate W.

In the substrate processing apparatus 1 brought into the status C, formation of the atmosphere separated space is released and the inside flow straightening member 14a moves up integrally with the lower sealing cup member 61, as shown in FIG. 8C. This generates a differential pressure between a space below the inside flow straightening member 14a and a space below the outside flow straightening member 14b. Thus, as shown by bold arrows in this figure, the flow rate of the cleaned air flowing downward from the outside flow straightening member 14b and along the outer side surface of the lower sealing cup member 61 (corresponding to an “outside flow rate” of the present invention) is increased. Specifically, the effect of suppressing flow of a foreign matter into the processing space SPc fulfilled by the air curtain AC is enhanced. As a result, even through formation of the atmosphere separated space is released, it is still possible to effectively suppress flow of a foreign matter into the processing space SPc. In the present embodiment, as described above, the flow rate of the cleaned air supplied vertically downward from the inside flow straightening member 14a (corresponding to an “inside flow rate” of the present invention) reduces while the flow rate of the cleaned air supplied vertically downward from the outside flow straightening member 14b increases. In response to this, flow rate adjustment using the damper 383 is changed. The damper 383 makes flow rate adjustment in such a manner as to realize (cup exhaust flow rate: chamber exhaust flow rate=3:7), for example. This makes it possible to prevent large fluctuation in a total amount of exhaust to be fed to the exhaust device 130 (=cup exhaust flow rate+chamber exhaust flow rate). This achieves the following effects. Specifically, the pertinent substrate processing apparatus 1 is connected in parallel to the other substrate processing apparatus 1 via the common pipe 131. Hence, the occurrence of large fluctuation in the total amount of exhaust from the pertinent substrate processing apparatus 1 might adversely affect the other substrate processing apparatus 1, causing a probability that substrate processing by the other substrate processing apparatus 1 will become unstable. In the present embodiment, however, the above-described ratio is changed in response to the status to suppress fluctuation in the total amount of exhaust. This prevents the occurrence of adverse effect on the other substrate processing apparatus 1, making it possible to perform stable substrate processing.

As described above, after the conveyance space sufficient to allow the entrance of the hand (not shown) of the substrate conveyor robot 111 is formed above the spin chuck 21 while flow of a foreign matter into the processing space SPc is prevented using the air curtain AC, the arithmetic processor 10A gives a loading request for the substrate W to the substrate conveyor robot 111 via the communicator 10F and waits until an unprocessed substrate W is carried into the substrate processing apparatus 1 along the conveyance path TP shown in FIG. 5 and placed on the upper surface of the spin chuck 21. Then, the substrate W is placed on the spin chuck 21 (Step S1). At this point of time, the pump 26 is stopped and the substrate W is horizontally movable on the upper surface of the spin chuck 21.

When loading of the substrate W is completed, the substrate conveyor robot 111 is retracted along the conveyance path TP from the substrate processing apparatus 1. Following that, as shown in FIG. 8D, while keeping the beam member 49, the support member 43, the disk part 42, the upper cup 33, and the lower sealing cup member 61 integrally positioned at the retracted position, the arithmetic processor 10A closes the shutter 15 (a status D in FIG. 13). When preparation for the centering processing is completed in this way, the arithmetic processor 10A controls the centering driver 83 so as to make the single mover 831 and the multi-contact part 82 approach the substrate W on the spin chuck 21. In this way, the eccentricity of the substrate W with respect to the spin chuck 21 is eliminated and the center of the substrate W coincides with that of the spin chuck 21 (Step S2). When the centering processing is completed in this way, the arithmetic processor 10A controls the centering driver 83 so as to separate the single mover 831 and the multi-contact part 82 from the substrate W, and operates the pump 26 to apply a negative pressure to the spin chuck 21. By doing so, the spin chuck 21 sucks and holds the substrate W from below.

Subsequently, the arithmetic processor 10A gives a move-down command to the elevation drivers 71, 72. In response to this, the elevation drivers 71, 72 integrally move down the lower sealing cup member 61, the nozzle head 56, the beam member 49, the support member 43 and the disk part 42. During these downward movements, the upper cup 33 supported from below by the projections 613 of the lower sealing cup member 61 is coupled to the lower cup 32. That is, the recesses 335 are fit to cover the tip parts of the engaging pins 35 as shown in FIG. 7, the upper cup 33 is positioned in the horizontal direction with respect to the lower cup 32 and the upper and lower cups 33, 32 are bonded to each other to form the rotating cup 31 by attraction forces generated between the upper and lower magnets 37, 36.

After the rotating cup 31 is formed, the lower sealing cup member 61, the nozzle head 56, the beam member 49, the support member 43, and the disk part 42 are further integrally moved down, and the flange parts 611 and 612 of the lower sealing cup member 61 are locked by the outside flow straightening member 14b and the fixed cup 34 respectively. In this way, the lower sealing cup member 61 is positioned at the lower limit position (position in FIG. 3) (Step S3). As a result, as shown in FIG. 8A, the lower sealing cup member 61 and the fixed cup 34 are connected to each other in the vertical direction Z, the sealed space 12a is formed by the upper sealing cup member 62, the lower sealing cup member 61, and the fixed cup 34, and the sealed space 12a is separated from the outside atmosphere (outside space 12b). In this way, the substrate processing apparatus 1 makes a shift from the status D to the status A to make a return to the atmosphere separated state suitable for the bevel processing, as shown in FIG. 8A.

In this atmosphere separated state, the lower surface of the disk part 42 covers the surface region excluding the peripheral edge part Ws, out of the upper surface Wf of the substrate W, from above. Further, the upper surface nozzles 51F are positioned in such a posture that the discharge ports are facing the peripheral edge part of the upper surface Wf of the substrate W in the cut 44 of the disk part 42. If preparation for the supply of the processing liquids to the substrate W is completed in this way, the arithmetic processor 10A gives a rotation command to the rotation driver 23 to start the rotation of the spin chuck 21 holding the substrate W and the rotating cup 31 (Step S4). Rotating speeds of the substrate W and the rotating cup 31 are set, for example, at 1800 rpm. Further, the arithmetic processor 10A controls the drive of the heater driver 422 to heat the heater 421 to a desired temperature, e.g. 185° C.

Next, the arithmetic processor 10A gives the heated gas supply command to the heated gas supplier 47. The nitrogen gas heated by the heater 471, i.e., the heated gas is thereby fed under pressure from the heated gas supplier 47 toward the center nozzle 45 (Step S5).

This heated gas is heated by the ribbon heater (not shown) during passing through the pipe (not shown).

This heated gas is thereby discharged from the center nozzle 45 sandwiched between the substrate W and the disk part 42 while a decrease in the temperature is prevented during the gas supply through the pipe (not shown). The entire upper surface Wf of the substrate W is thereby heated. Further, the substrate W is also heated by the heater 421. For this reason, the temperature of the peripheral edge part Ws of the substrate W rises with the passage of time and reaches a temperature suitable for the bevel processing, e.g. 90° C. Further, the temperature of the substrate W other than the peripheral edge part Ws also rises to a substantially equal temperature. In other words, in the present embodiment, the in-plane temperature of the upper surface Wf of the substrate W is substantially uniform. Therefore, the warping of the substrate W can be effectively suppressed.

Following this, the arithmetic processor 10A supplies the processing liquids to the upper surface nozzles 51F and the lower surface nozzles 51B by controlling the processing liquid suppliers 52. That is, flows of the processing liquids are discharged from the upper surface nozzles 51F to contact the peripheral edge part of the upper surface of the substrate W, and flows of the processing liquids are discharged from the lower surface nozzles 51B to contact the peripheral edge part of the lower surface of the substrate W. In this way, the bevel processing is performed on the peripheral edge part Ws of the substrate W (Step S6). Upon detecting the passage of a processing time required for the bevel processing of the substrate W, the arithmetic processor 10A gives a supply stop command to the processing liquid suppliers 52 to stop the discharge of the processing liquids.

Following that, the arithmetic processor 10A gives a supply stop command to the nitrogen gas supplier 47 to stop the supply of the nitrogen gas from the nitrogen gas supplier 47 to the center nozzle 45 (Step S7). Further, the arithmetic processor 10A gives a rotation stop command to the rotation driver 23 to stop the rotation of the spin chuck 21 and the rotating cup 31 (Step S8).

In next Step S9, the arithmetic processor 10A observes the peripheral edge part Ws of the substrate W to inspect a result of the bevel processing.
More specifically, the arithmetic processor 10A controls each part of the equipment so that the substrate processing apparatus 1 is in status D. Then, the arithmetic processor 10A controls the observation head driver 94 to bring the observation head 93 closer to the substrate W. Then, the arithmetic processor 10A lights the light source part 91 to illuminate the peripheral edge part Ws of the substrate W through the observation head 93. Further, the image pickup part 92 receives the reflected light which is reflected by the peripheral edge part Ws and the adjacent area, to thereby image the peripheral edge part Ws and the adjacent area. Specifically, a peripheral-edge-part image of the peripheral edge part Ws along the rotation direction of the substrate W is acquired out of a plurality of images of the peripheral edge part Ws acquired by the image pickup part 92 while the substrate W is rotated about the axis of rotation AX. Then, the arithmetic processor 10A controls the observation head driver 94 to retract the observation head 93 from the substrate W. In parallel with this, the arithmetic processor 10A inspects whether or not the bevel processing has been satisfactorily performed, on the basis of the picked-up image of the peripheral edge part Ws and the adjacent area, i.e., the peripheral-edge-part image. Further, in the present embodiment, as an example of the inspection, a processing width is inspected from the peripheral-edge-part image, which is processed by using the processing liquids, from the end surface of the substrate W toward the central part of the substrate W (inspection after processing).

After the inspection, the arithmetic processor 10A opens the shutter 15 to shift the substrate processing apparatus 1 from the status D to the status C, as shown in FIG. 8C. Furthermore, the arithmetic processor 10A gives an unloading request for the substrate W to the substrate conveyor robot 111 via the communicator 10F, and the processed substrate W is unloaded from the substrate processing apparatus 1 (Step S10). This series of steps is repeatedly performed.

As described above, in the present embodiment, as shown in FIG. 8A, positioning the lower sealing cup member 61 at the lower limit position forms the atmosphere separated space using the lower sealing cup member 61 and the upper sealing cup member 62 to atmosphere-separate the processing space SPc from a surrounding environment. This makes it possible to effectively prevent flow of a foreign matter into the processing space SPc during the bevel processing. Furthermore, for implementations of substrate conveyance, the centering processing, the observation processing, and others, formation of the atmosphere separated space is released in response to upward movement of the lower sealing cup member 61. In this regard, as shown in FIGS. 8B to 8D, the flow rate of the cleaned air flowing out into the outside space 12b via the outside flow straightening member 14b increases in response to a differential pressure generated as the inside flow straightening member 14a moves up integrally with the lower sealing cup member 61. This also increases the flow rate of the cleaned air forming the air curtain AC configured in such a manner as to surround the processing space SPc, thereby enhancing the barrier performance of the air curtain AC. As a result, it is possible to suppress flow of a foreign matter into the processing space SPc effectively using the air curtain AC.

In the present embodiment, as shown in FIGS. 8B and 8C, formation of the atmosphere separated space continues until opening of the shutter 15 is completed. This makes it possible to shorten a period when formation of the atmosphere separated space is released. As a result, it is possible to suppress flow of a foreign matter into the processing space SPc more effectively.

In the present embodiment, moving up the inside flow straightening member 14a integrally with the lower sealing cup member 61 increases the ratio of the cleaned air as part of the cleaned air supplied from the fan filter unit 13 and to flow toward the outside flow straightening member 14b, thereby enhancing the barrier performance of the air curtain AC. Thus, it is not required to provide a drive mechanism dedicated to reinforce the air curtain AC during loading and unloading of the substrate W, the centering processing, the observation processing, the maintenance processing, and others. This makes it possible to suppress flow of a foreign matter into the processing space SPc with reduced energy. Additionally, the amount of the cleaned air to be supplied from the fan filter unit 13 is not required to be increased for the reinforcement of the air curtain AC. This achieves reduction in the amount of consumption of the cleaned air while encouraging extended life of the fan filter unit 13.

In the present embodiment, the scattering preventing mechanism 3 and the atmosphere separating mechanism 6 have circular shapes in a plan view of the chamber 11 viewed from above. Thus, a gas outlet (not shown) of the fan filter unit 13 for blowing out the cleaned air is finished into a circular shape in a plan view from a side of the atmosphere separating mechanism 6. Furthermore, the center of the gas outlet is arranged in such a manner as to substantially coincide with the axis of rotation AX. By doing so, the cleaned air is supplied uniformly to the atmosphere separated space and the flow rate of the cleaned air forming the air curtain AC also becomes uniform within a horizontal plane. This causes the air curtain AC to prevent a foreign matter on the move from any horizontal direction from flowing into the processing space SPc. As a result, it is possible to suppress incoming flow of a foreign matter stably.

In the present embodiment, the flow rate of the cleaned air flowing into the sealed space 12a and the flow rate of the cleaned air flowing into the outside space 12b are changed as the inside flow straightening member 14a moves up and down integrally with the lower sealing cup member 61. The damper 383 adjusts a ratio between the cup exhaust flow rate and the chamber exhaust flow rate in response to these changes. Thus, in the substrate processing apparatus 1, while switch is made between formation of the atmosphere separated space and release of the formation in response to the upward and downward movements of the lower sealing cup member 61, it is possible to maintain the total amount of exhaust constantly. In particular, in the substrate processing system 100, connecting a plurality of the substrate processing apparatuses 1 in parallel to each other via the common pipe 131 does not cause a problem that the change in the total amount of exhaust in one of the substrate processing apparatuses 1 will adversely affect the other substrate processing apparatus 1. Thus, it is possible to perform the bevel processing stably in each substrate processing apparatus 1.

The on/off valve 384 is provided for each substrate processing apparatus 1. By closing the on/off valve 384 for implementation of maintenance processing described next, for example, the substrate processing apparatus 1 can be separated from the other substrate processing apparatus 1. This makes it possible to perform the maintenance processing at one substrate processing apparatus 1 and the bevel processing at the other substrate processing apparatus 1 stably in parallel with each other.

In the above-described substrate processing apparatus 1, the four types of statuses A to D are prepared for the bevel processing (substrate processing). As shown in FIG. 14, three types of statuses are prepared in response to a substance of the maintenance processing.

FIG. 14 is a diagram showing a state in each part of the apparatus corresponding to each status of the maintenance processing. FIG. 15A is a diagram schematically showing a status in each part of the apparatus during first maintenance processing. FIG. 15B is a diagram schematically showing a status in each part of the apparatus during second maintenance processing. FIG. 15C is a diagram schematically showing a status in each part of the apparatus during third maintenance processing. As shown in FIGS. 15A to 15C, for implementation of the maintenance processing, the on/off valve 384 is closed and connection is cut between the other substrate processing apparatus 1 and the exhaust device 130. In the disconnected state, an operator removes the lid member 19 from the chamber 11 to open the maintenance opening 11d1.

Meanwhile, as shown in FIGS. 14 and 15A, for implementation of the first maintenance processing, the arithmetic processor 10A opens the shutter 15 and positions the lower sealing cup member 61 at the retracted position. This allows the operator to access the internal space 12 both from the conveyance opening 11b1 and the maintenance opening 11d1. Furthermore, the lower sealing cup member 61, the nozzle head 56, the beam member 49, the support member 43, and the disk part 42 are integrally positioned at the retracted position. This allows the operator to further access the processing space SPc. In this state of a status E, as the conveyance opening 11b1 and the maintenance opening 11d1 are opened, a foreign matter might flow in via these openings. Like in the statuses C and D, however, the flow rate of the cleaned air forming the air curtain AC is increased to enhance the barrier performance of the air curtain AC. As a result, it is possible to suppress flow of a foreign matter into the processing space SPc effectively using the air curtain AC.

As shown in FIGS. 14 and 15B, for implementation of the second maintenance processing, the arithmetic processor 10A opens the shutter 15 and positions the lower sealing cup member 61 at the lower limit position. This forms the atmosphere separated space to prohibit access to the processing space SPc. Meanwhile, the operator is allowed to access the internal space 12 both from the conveyance opening 11b1 and the maintenance opening 11d1. In this state of a status F, as in the statuses A and B, the processing space SPc is atmosphere separated. Thus, while opening the conveyance opening 11b1 and the maintenance opening 11d1 might cause incoming flow of a foreign matter via these openings, this atmosphere separation suppresses flow of a foreign matter into the processing space SPc.

For implementation of the third maintenance processing, specifically, for implementation of maintenance by accessing the internal space 12 only from one of the conveyance opening 11b1 and the maintenance opening 11, the arithmetic processor 10A closes the shutter 15 and may position the lower sealing cup member 61 either at the lower limit position (status G) as shown in FIGS. 14 and 15C, for example, or at the retracted position. In either case, the operator is allowed to access the internal space 12 from the maintenance opening 11d1. In the latter case, the lower sealing cup member 61, the nozzle head 56, the beam member 49, the support member 43, and the disk part 42 are integrally positioned at the retracted position. This allows the operator to also access the processing space SPc from the maintenance opening 11d1. In the state of this status, the flow rate of the cleaned air forming the air curtain AC is increased to enhance the barrier performance of the air curtain AC, like in the case of implementation of the first maintenance processing. As a result, it is possible to suppress flow of a foreign matter into the processing space SPc effectively using the air curtain AC. Additionally, the maintenance opening 11d1 may be closed in the state of FIG. 15A or in the state of FIG. 15B. In both of these cases, the operator is allowed to access the internal space 12 from the conveyance opening 11b1, thereby achieving effects comparable to those described above.

As described above, in the above-described embodiment, the opening 11f1, the conveyance opening 11b1, and the maintenance opening 11d1 correspond to one example of a “first opening,” one example of a “second opening,” and one example of a “third opening” of the present invention respectively. The fan filter unit 13 corresponds to one example of a “gas supplier” of the present invention. The upper sealing cup member 62 and the lower sealing cup member 61 correspond to one example of an “upper sealing member” and one example of a “lower sealing member” of the present invention respectively. The cleaned air corresponds to one example of “gas” of the present invention. The cup exhaust flow rate and the chamber exhaust flow rate correspond to one example of a “first exhaust flow rate” and one example of a “second exhaust flow rate” of the present invention respectively. The damper 383 corresponds to one example of a “exhaust flow rate adjuster”of the present invention.

Furthermore, the present invention is not limited to the above-described embodiment and numerous modifications and variations can be added to those described above without departing from the scope of the invention. In the above-described embodiment, for example, in the substrate processing apparatus 1, the present invention is applied to a substrate processing apparatus having a raised floor structure in which the substrate processing part SP is installed on the upper surface of the base member 17. Furthermore, in the above-described embodiment, the present invention is applied to a substrate processing apparatus having the rotating cup 31. Moreover, in the above-described embodiment, the present invention is applied to a substrate processing apparatus having the upper surface protecting/heating mechanism 4, the atmosphere separating mechanism 6, the centering mechanism 8, and the substrate observing mechanism 9. As described in, for example, Patent Document 1, however, the present invention can be applied to a substrate processing apparatus without these structures, namely, to a substrate processing apparatus in general which processes the peripheral edge part of the substrate W by supplying a processing liquid to the peripheral edge part of the substrate W in the internal space 12 of the chamber 11.

In the above-described embodiment, exhaust of the plurality of substrate processing apparatuses 1 is realized by the single exhaust device 130. Alternatively, in one configuration, an exhaust unit may be provided for each substrate processing apparatus 1.

In the above-described embodiment, the inside flow straightening member 14a and the outside flow straightening member 14b are composed of punching plates. However, flow straightening members of a different type such as a louvered type may be used.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

### INDUSTRIAL APPLICABILITY

This invention is applicable to substrate processing techniques in general for processing a substrate by supplying a processing liquid to the substrate.

### REFERENCE SIGNS LIST

1 . . . substrate processing apparatus
2A . . . substrate holder
2B . . . rotating mechanism
3 . . . scattering preventing mechanism
5 . . . processing mechanism
6 . . . atmosphere separating mechanism
7 . . . elevating mechanism
8 . . . centering mechanism
9 . . . substrate observing mechanism
10 . . . control unit
10A . . . arithmetic processor
10G . . . exhaust controller
11 . . . chamber
11b1 . . . conveyance opening
11d1 . . . maintenance opening
11f1 . . . (first) opening
12 . . . internal space
12al . . . sealed space
12b . . . outside space
13. . . . fan filter unit (gas supplier)
14a . . . inside flow straightening member
14b . . . outside flow straightening member
15 . . . shutter
19 . . . lid member
21 . . . spin chuck
61 . . . lower sealing cup member (lower sealing member)
62 . . . upper sealing cup member(upper sealing member)
100 . . . substrate processing system
130 . . . exhaust device
383 . . . damper (exhaust flow rate adjuster)
384 . . . on/off valve
AC . . . air curtain
AX . . . axis of rotation
SPc . . . processing space
Z . . . vertical direction

1. A substrate processing apparatus, comprising:
a chamber having an internal space;
a spin chuck provided rotatably about an axis of rotation extending in a vertical direction while holding a substrate to be substantially horizontal in the internal space;
a processing mechanism configured to perform substrate processing on the substrate by supplying a processing liquid to the substrate held by the spin chuck;
a first cup configured to collect and discharge the processing liquid scattered from the substrate by the rotation of the spin chuck while surrounding an outer periphery of the substrate;
a fan filter unit configured to supply gas from a first opening provided in a ceiling wall of the chamber into the internal space;
a second cup having a tube-shape upper sealing member and a tube-shape lower sealing member and being configured to allow formation of an atmosphere separated space separated from a surrounding environment by causing the lower sealing member and the upper sealing member to surround a space extending toward a central part of the first opening from a processing space surrounded by the first cup, the tube-shape upper sealing member being attached from a side of the internal space to the ceiling wall in such a manner as to surround the first opening entirely, the tube-shape lower sealing member being provided movably in the vertical direction with an outer peripheral surface of the lower sealing member overlapping an inner peripheral surface of the upper sealing member in the vertical direction;
an outside flow straightening member attached to the upper sealing member in such a manner as to straighten the flow of the gas passing between the upper sealing member and the lower sealing member to cause the gas to flow downward along an outer side surface of the lower sealing member;
an inside flow straightening member provided movably up and down integrally with the lower sealing member in such a manner as to straighten the flow of the gas passing inside the lower sealing member to cause the gas to flow in the processing space;
a motor configured to move the lower sealing member up and down; and
a controller configured to control the motor in such a manner as to form the atmosphere separated space by moving the lower sealing member down to a predetermined lower limit position in the vertical direction, and to allow access to the processing space and to increase the flow rate of the gas flowing downward along the outer side surface of the lower sealing member by moving the lower sealing member up to a retracted position vertically above the lower limit position.

2. The substrate processing apparatus according to claim 1, wherein
with the flow rate of the gas per unit time flowing toward the processing space via the inside flow straightening member defined as an inside flow rate and with the flow rate of the gas per unit time flowing along the outer side surface of the lower sealing member via the outside flow straightening member defined as an outside flow rate,
the inside flow straightening member and the outside flow straightening member are finished in such a manner that the inside flow rate becomes greater than the outside flow rate when the lower sealing member is positioned at the lower limit position.

3. The substrate processing apparatus according to claim 2, wherein
the outside flow straightening member is a punching plate prepared by perforating a disk-like plate surrounding the lower sealing member with a plurality of outside through holes, and
the inside flow straightening member is a punching plate prepared by perforating a plate surrounded by the lower sealing member with inside through holes of a larger number than the outside through holes, the inside through holes having a smaller diameter than the outer through holes.

4. The substrate processing apparatus according to claim 1, comprising:
a shutter configured to open and close a second opening provided in a side wall of the chamber, wherein
in order to load the substrate into or unload the substrate from the spin chuck via the second opening, the controller is configured to control the shutter in such a manner that the lower sealing member is positioned at the lower limit position until opening of the second opening using the shutter is completed and that the lower sealing member moves to the retracted position after opening of the second opening is completed.

5. The substrate processing apparatus according to claim 1, comprising:
a centering mechanism configured to perform centering processing of making coincidence of a center of the substrate with the axis of rotation by bringing a contact part into contact with the substrate placed movably in a horizontal direction on the spin chuck, wherein
the controller is configured to control the motor in such a manner as to position the lower sealing member at the retracted position during the centering processing.

6. The substrate processing apparatus according to claim 1, comprising:
a substrate observing mechanism configured to perform observation processing of observing a peripheral edge part of the substrate held by the spin chuck, wherein
the controller is configured to control the motor in such a manner that the lower sealing member is positioned at the retracted position during the observation processing.

7. The substrate processing apparatus according to claim 1, comprising:
a lid member detachably attached to a side wall of the chamber in such a manner as to close a third opening provided in the side wall of the chamber, wherein
in order for an operator to access the internal space and perform maintenance processing, the controller is configured to control the motor in such a manner that the lower sealing member is positioned at the lower limit position until the lid member is detached from the side wall of the chamber and that the lower sealing member moves to the retracted position after detachment of the lid member is completed.

8. The substrate processing apparatus according to claim 1, wherein
the fan filter unit has a gas outlet having a circular shape in a plan view vertically from above and viewed from a side of the second cup,

9. The substrate processing apparatus according to claim 1, comprising:
a first exhaust pipe for exhausting the processing space;
a second exhaust pipe for exhausting the internal space other than the processing space;
an exhaust unit configured to exhaust the internal space via the first exhaust pipe and the second exhaust pipe; and
a damper configured to make a ratio adjustable between a first exhaust flow rate of exhaust via the first exhaust pipe and a second exhaust flow rate of exhaust via the second exhaust pipe, wherein
while the exhaust unit maintains an exhaust flow rate per unit time constantly, the controller is configured to control the damper in such a manner as to make the ratio of the first exhaust flow rate higher when the lower sealing member is positioned at the lower limit position and to make the ratio of the second exhaust flow rate higher when the lower sealing member is positioned at the retracted position.

10. A substrate processing method of performing substrate processing on a substrate by supplying a processing liquid to the substrate while causing a first cup to surround an outer periphery of the substrate rotating in an internal space of a chamber to which gas is supplied via a first opening provided in a ceiling wall of the chamber, the method comprising:
(a) forming an atmosphere separated space which surrounds a space extending toward a central part of the first opening from a processing space surrounded by the first cup and is separated from a surrounding environment by moving a tube-shape lower sealing member down to a predetermined lower limit position in a vertical direction while making an overlap of an outer peripheral surface of the lower sealing member in the vertical direction with an inner peripheral surface of a tube-shape upper sealing member attached from a side of the internal space to the ceiling wall in such a manner as to surround the first opening entirely; and
(b) releasing formation of the atmosphere separated space and forming a gap between the lower sealing member and the first cup in the vertical direction by moving the lower sealing member up to a retracted position vertically above the lower limit position, wherein
the operation (a) includes (a-1) straightening the flow of the gas passing between the upper sealing member and the lower sealing member using an outside flow straightening member attached to the upper sealing member and causing the gas to flow downward along an outer side surface of the lower sealing member, and (a-2) straightening the flow of the gas passing inside the lower sealing member using an inside flow straightening member provided movably integrally with the lower sealing member and causing the gas to flow in the processing space, and
the operation (b) includes a step of making the flow rate of the gas flowing downward along the outer side surface of the lower sealing member higher than a flow rate in the first step as the inside flow straightening member moves up integrally with the lower sealing member.

11. A substrate processing system comprising:
a plurality of the substrate processing apparatuses according to claim 1; and
an exhaust device connected in parallel to the plurality of substrate processing apparatuses and configured to exhaust a plurality of the internal spaces simultaneously, wherein
each of the plurality of substrate processing apparatuses includes:
a first exhaust pipe forming connection between the processing space and the exhaust device;
a second exhaust pipe forming connection between a space in the internal space and other than the processing space and the exhaust device; and
a damper configured to make a ratio adjustable between a first exhaust flow rate of exhaust via the first exhaust pipe and a second exhaust flow rate of exhaust via the second exhaust pipe, wherein
the controller is configured to control the damper in such a manner that an exhaust flow rate of exhaust per unit time by the exhaust device from the internal space becomes constant by making the ratio of the first exhaust flow rate higher when the lower sealing member is positioned at the lower limit position and making the ratio of the second exhaust flow rate higher when the lower sealing member is positioned at the retracted position.

12. The substrate processing system according to claim 11, wherein
the substrate processing apparatuses are stacked in the vertical direction, and
the exhaust device is arranged above the substrate processing apparatus at the highest position in the vertical direction.
